(19) United States
(12) Patent Application Publication
(10) Pub. No.: US 2026/0366916 A1
(43) Pub. Date: Nov. 19, 2026

(54) HYPERSPECTRAL IMAGING SPECTROMETER WITH LOW DISTORTION, LARGE IMAGE PLANE, AND OBJECT- AND IMAGE-SPACE TELECENTRICITY, AND IMPLEMENTATION METHOD THEREOF

(71) Applicant: SHANGHAI INSTITUTE OF TECHNICAL PHYSICS CHINESE ACADEMY OF SCIENCES, Shanghai (CN)

(72) Inventors: Yinnian Liu, Shanghai (CN); Qian Chen, Shanghai (CN); Zongcun Zhang, Shanghai (CN); Youlong Ke, Shanghai (CN); Shufeng Liu, Shanghai (CN); Guoqing Liu, Shanghai (CN); Jialin Sun, Shanghai (CN); Dexin Sun, Shanghai (CN)

(21) Appl. No.: 19/723,037

(22) Filed: Jun. 29, 2026

Related U.S. Application Data
(63) Continuation-in-part of application No. PCT/CN2025/122372, filed on Sep. 18, 2025.

(30) Foreign Application Priority Data
Mar. 21, 2025 (CN) 202510337505.5

(51) Int. Cl. G01J 3/02; G01J 3/04; G01J 3/28; G06F 30/17

(52) U.S. Cl. CPC G01J 3/0208; G01J 3/04; G01J 3/2803; G06F 30/17; G01J 2003/045; G01J 2003/2813

(57) ABSTRACT

Provided are a hyperspectral imaging spectrometer with low distortion, a large image plane, and object- and image-space telecentricity, and an implementation method thereof. The implementation method includes: establishing a theoretical model for object- and image-space telecentricity of the spectrometer, that is, establishing three sub-models: “spectral smile-telecentricity”, “spectral keystone-telecentricity”, and “astigmatism-telecentricity”; and giving a relationship between telecentricity and parameters of the spectrometer's field stop, meniscus lens, primary/secondary reflector, and convex grating based on the theoretical model, enabling rapid design of the spectrometer's initial structure parameters. A novel spectrometer featuring a large field of view, low astigmatism, low spectral keystone, and low spectral lateral deviation is successfully designed through this method, to resolve spectrometers' inherent problem that blur and distortion non-linearly surge as a field of view increases. A fundamental change is achieved, in which blur and distortion remain nearly constant in a large field of view.

### CROSS REFERENCE TO RELATED APPLICATIONS

The present application is a Continuation-In-Part Application of PCT Application No. PCT/CN2025/122372 filed on Sep. 18, 2025, which claims the benefit of Chinese Patent Application No. 202510337505.5 filed on Mar. 21, 2025, the contents of which are incorporated herein by reference in their entirety.

### TECHNICAL FIELD

The present disclosure belongs to the technical field of optical instruments, and relates to a spectrometer and a design and implementation method thereof, and in particular, to an implementation method of a hyperspectral imaging spectrometer with low distortion, a large image plane, and object- and image-space telecentricity.

### BACKGROUND

A hyperspectral imaging technology can simultaneously obtain geometric, radiometric, and spectral information of targets. It enriches dimensions of target cognition, achieves a leap from macro to micro, and offers a unique advantage in identifying material “fingerprints”, demonstrating great application potential in energy resource exploration, environmental disaster monitoring, agricultural and forestry remote sensing, greenhouse gas monitoring, urban surveying, and the like. The hyperspectral imaging technology was included in the “100 Radical Innovation Breakthroughs for the Future” report published by the European Union in 2021, recognized as one of disruptive technologies that could have significant impact on global economy.

As one of core optical components in the hyperspectral imaging technology, a spectrometer decomposes light reflected or radiated by an object into spectral information of different wavelengths, and obtains a complete spectral curve of each spatial pixel in combination with an imaging system, to classify and identify different objects. The spectrometer's hyperspectral resolution enables accurate capture of a material's absorption, reflection, or transmission characteristics for light at various wavelengths. These spectral characteristics can reflect the material's physicochemical properties. These data can be further processed for tasks such as material classification, composition identification, and defect detection.

Since the end of the last century, countries around the world have been racing to develop the hyperspectral imaging technology. At present, there are more than 30 hyperspectral satellites in orbit, under development, or in planning. However, issues such as a narrow swath for ground surveys and insufficient spectral accuracy result in low timeliness and poor application effectiveness of hyperspectral detection data. This prevents operationalization and widespread practical adoption of spaceborne hyperspectral remote sensing instruments. A root cause lies in that a traditional imaging design method based on a third-order aberration theory focuses solely on geometric blur and geometric astigmatism. Spectral keystone and spectral lateral deviation used to measure a quantitative accuracy level of a hyperspectral imaging system are weakened or even ignored, resulting in low accuracy of both spatial and spectral dimensions of hyperspectral data and thus an anomalous phenomenon of “different spectra for a same object” and “a same spectrum for different objects”. To achieve high imaging quality with low blur, low spectral keystone, and low spectral lateral deviation, a conventional spectrometer can only implement a narrow linear field of view, and its field of view “cannot be lengthened or broadened”.

In 2000, a Hyperion hyperspectral camera aboard a U.S. EO-1 satellite implemented an Offner spectrometer structure based on a convex grating in orbit, featuring a linear field of view of approximately 15 mm (Folkman M A, Pearlman J, Liao L B, et al. EO-1/Hyperion hyperspectral imager design, development, characterization, and calibration [J]. Hyperspectral Remote Sensing of the Land and Atmosphere, 2001, 4151:40-51.). The inventors implemented a convex grating spectrometer with an Offner structure in 2002 (Shen Beijun, Liu Baoli, Liu Yinnian, et al. Catadioptric Convex Grating Imaging Optical System: CN02136154.1 [P]), achieving good control over image quality, spectral keystone, and spectral smile in a field of view of 20 mm. Beyond this limit, image quality, spectral keystone, and spectral lateral deviation deteriorate sharply. This has become a bottleneck limiting further expansion of the field of view of spaceborne hyperspectral detection around the world. The inventor first introduced a novel Offner spectrometer structure in 2011 (Yang Bo. Research on Optical Technology of Wide-Swath Hyperspectral Imaging [D]. Graduate University of Chinese Academy of Sciences, 2011.). Based on a traditional aberration theory and optical software such as ZEMAX, a design idea of object- and image-space telecentricity was applied for the first time to design of a convex grating spectrometer with an ultra-large field of view of 60 mm. In 2018, the world's first wide-spectrum and wide-swath hyperspectral camera (AHSI) was deployed in orbit (Liu Y N, Sun D X, Hu X N, et al. The advanced hyperspectral imager: Aboard China's GaoFen-5 satellite [J]. IEEE Geoscience and Remote Sensing Magazine, 2019, 7(4): 23-32.). On the premise that a spectral range (0.4 μm to 2.5 μm) and a spatial resolution (30 m) of the wide-spectrum and wide-swath hyperspectral camera are the same as those of international mainstream spaceborne hyperspectral cameras, a swath width of the wide-spectrum and wide-swath hyperspectral camera has been increased from globally prevalent 30 km to 60 km, spectral keystone thereof is close to 0.1 pixels, and a spectral lateral deviation thereof is less than 1 nm, achieving internationally leading accuracy. It is widely recognized by experts and scholars around the world as a benchmark for high-quantitative hyperspectral detection, marking a milestone achievement.

Subsequently, Jia. C. Zhu et al. studied an astigmatism expression of the foregoing novel Offner spectrometer structure featuring a large field of view, low spectral keystone, and low spectral lateral deviation, and proved that the novel Offner spectrometer has a larger astigmatism-free field of view than a conventional Offner spectrometer from the perspective of astigmatism elimination (Zhu Jiacheng, Shen Weimin. Compact Astigmatism-Free Long-Slit Spectrometer Optical System [J]. Journal of Infrared and Millimeter Waves, 2019, 38(4): 7.). X. Prieto studied two Offner spectrometer structures with a meniscus lens, and confirmed the large field of view and high image quality of the novel Offner spectrometer from the perspective of aberration elimination (Prieto-Blanco X, de la Fuente R. Compact Offner-Wynne imaging spectrometers [J]. Optics Communications, 2014, 328:143-150.). However, none of them provided a theoretical model for object- and image-space telecentricity, a corresponding initial structure design method, and corresponding engineering application constraints.

### SUMMARY

The present disclosure provides an implementation method of a hyperspectral imaging spectrometer with low distortion, a large image plane, and object- and image-space telecentricity, including: establishing a theoretical model for object- and image-space telecentricity of the spectrometer, and designing initial structure parameters of the spectrometer based on the theoretical model. The method is used to implement a novel spectrometer featuring a large field of view, high image quality, and extremely low spectral keystone and lateral deviation.

The theoretical model for object- and image-space telecentricity of the spectrometer is established. The theoretical model is composed of three sub-models: “spectral smile-telecentricity”, “spectral keystone-telecentricity”, and “astigmatism-telecentricity”. The “spectral smile-telecentricity” model describes a mapping relationship of spectral smile (e) with object-space telecentricity (a) and image-space telecentricity (b). The “spectral keystone-telecentricity” model describes a mapping relationship of spectral keystone (d) with object-space telecentricity (a) and image-space telecentricity (b). The “astigmatism-telecentricity” model describes a mapping relationship of astigmatism (c) with object-space telecentricity (a) and image-space telecentricity (b). Specific relations are as follows:

The “spectral smile-telecentricity” model (e-ab) is as follows:

$${ε}_{s} = \frac{d {y}_{i}}{d {x}_{o}} = [ {y}_{o} tan {ϕ}_{o} \cdot \frac{d {ϕ}_{o}}{d {x}_{o}} + ( \frac{{R}_{g} \cdot mg λ}{cos {ϕ}_{o}} - {y}_{o} ) \cdot tan {ϕ}_{i} \cdot \frac{d {ϕ}_{i}}{d {x}_{o}} ] \cdot \frac{cos {ϕ}_{o}}{cos {ϕ}_{i}}$$

The “spectral keystone-telecentricity” model (d-ab) is as follows:

$${ε}_{k} = \frac{d {x}_{i}}{d λ} = [ tan {ϕ}_{o} \frac{d {ϕ}_{o}}{d λ} - tan {ϕ}_{i} \cdot \frac{d {ϕ}_{i}}{d λ} ] \cdot {x}_{o} \cdot \frac{cos {ϕ}_{o}}{cos {ϕ}_{i}}$$

The “astigmatism-telecentricity” model (c-ab) is as follows:

$${ε}_{a} = \frac{sin {α}_{o}}{sin {α}_{i}} \cdot CO \cdot tan [ {ϕ}_{i} + arctan ( \frac{sin {α}_{i}}{sin {α}_{o}} \cdot tan {ϕ}_{o} ) ]$$

εₛ is a value of spectral smile (e). εₖ is a value of spectral keystone (d). εₐ is a value of astigmatism (c). φₒ is the object-space telecentricity, with clockwise as a positive direction. φᵢ is the image-space telecentricity, with counterclockwise as a positive direction. (xₒ, yₒ) are coordinates of an object point. (xᵢ, yᵢ) are coordinates of an image point. R₂ is a radius of curvature of a convex grating. m is a diffraction order. g is a groove density of the convex grating. λ is a wavelength. αₒ is an incident azimuth angle of a principal ray of the spectrometer, and αᵢ is an emergent azimuth angle of the principal ray of the spectrometer, with clockwise as a positive direction. CO is a distance from the object point of the spectrometer to a common center of curvature of all reflectors, i.e., a primary reflector and a secondary reflector.

Based on the foregoing theoretical model combined with engineering implementation of a spectrometer with low distortion, a large image plane, and object- and image-space telecentricity, parameters of the spectrometer need to satisfy the following formula:

$$\{ \begin{matrix}tan {ϕ}_{o} \cdot \frac{d {ϕ}_{o}}{{dx}_{o}} {\vert}_{{x}_{o} = {x}_{{o}_{1 ∼ ∞}}} = tan {ϕ}_{i} \cdot \frac{d {ϕ}_{i}}{{dx}_{o}} {\vert}_{{x}_{o} = {x}_{{o}_{1 ∼ ∞}}} = 0 \\ tan {ϕ}_{o} \cdot \frac{d {ϕ}_{o}}{d λ} {\vert}_{λ = {λ}_{1} ∼ {λ}_{n}} = tan {ϕ}_{i} \cdot \frac{d {ϕ}_{i}}{d λ} {\vert}_{λ = {λ}_{1} ∼ {λ}_{n}} = 0\end{matrix}$$

φₒ is the object-space telecentricity. φᵢ is the image-space telecentricity. (xₒ, yₒ) are the coordinates of the object point. xₒ=xₒ_{_{1~∞}} is a central field position to an edge field position of any slit in the slits of the spectrometer. λ is the wavelength. λ₁-λₙ is an operating wavelength range of the spectrometer. λ₁ is a start wavelength. λₙ is an end wavelength.

A condition of flattening a sagittal field curvature is based on the “astigmatism-telecentricity” model. Each of the slits is located on a plane XCY perpendicular to an optical axis and passing through a common center of curvature of all optical surfaces (any slit in the slits is parallel to an x-axis, a zₒ coordinate of any point on any slit in the slits is zero, zₒ is a Z coordinate of the object point, and any slit in the slits is at a distance of yₒ from the common center of curvature C).

A basic idea of a method for obtaining an initial structure is as follows: First, establish a parameter relationship between the object-space telecentricity and the image-space telecentricity (a and b) and off-axis distances (yₒ₁ and yₒ₂) of a field stop of the spectrometer, radii of curvature (R₁ and R₂) of a meniscus lens, a radius of curvature (R₃) of the primary reflector, a radius of curvature (R₄) of the secondary reflector and the radius of curvature (R₂) of the convex grating.

Then, obtain, based on the relationship, initial structure parameters meeting a telecentricity requirement. Finally, determine the initial structure parameters R₁, R₂, R₃, and R₄ of the spectrometer, and the off-axis distances yₒ₁ and yₒ₂ of the slits. A specific process of determining the initial structure includes steps S51 to S57. S51: Obtain a first input parameter and a second input parameter. S52: Obtain an intermediate parameter based on the first input parameter and the second input parameter. S53: Solve an object-space telecentricity model and an image-space telecentricity model. S54: Obtain the initial structure parameters. S55: Determine whether an initial structure corresponding to the initial structure parameters blocks light. S56: Determine whether the initial structure meets a spectral detection requirement for engineering application. S57: If the conditions in S55 and S56 are satisfied, output the initial structure parameters and establish the initial structure of the spectrometer.

In the present disclosure, a first surface distribution and a second surface distribution are first obtained based on the theoretical model. The first surface distribution is a surface distribution of structure parameters of the meniscus lens and the primary reflector with respect to a two-dimensional rectangular field of view when object-space telecentricity is achieved. A curve function of the structure parameters is as follows:

$${ϕ}_{o} = {\sum }_{i = 1}^{3} {k}_{1 i} arcsin ( \frac{CO}{{n}_{1 i} {R}_{i}} ) - {\sum }_{j = 1}^{2} {k}_{2 j} arcsin ( \frac{CO}{{n}_{2 j} {R}_{j}} )$$

k₁₃=2, and k₁ᵢ=1 for other values of i. n₁₂=n, and n₁ᵢ=1 for other values of i. k₂₂=2, and k₂ⱼ=1 for other values of j. n₂₁=n, and n₂ⱼ=1 for other values of j. CO is the distance from the object point of the spectrometer to the common center of curvature of all optical surfaces:

CO=\sqrt{xₒ²+yₒ²}

The second surface distribution is a surface distribution of structure parameters of the meniscus lens and the secondary reflector with respect to the two-dimensional rectangular field of view when image-space telecentricity is achieved. A curve function of the structure parameters is as follows:

$${ϕ}_{i} = {\sum }_{i = 1}^{4} {k}_{1 i} arcsin ( \frac{CI}{{n}_{1 i} {R}_{i}} ) - {\sum }_{j = 1}^{2} {k}_{2 j} arcsin ( \frac{CI}{{n}_{2 j} {R}_{j}} )$$

k₁₄=2, k₁₃=0, and k₁ᵢ=1 for other values of i. n₁₂=n, and n₁ᵢ=1 for other values of i. k₂₂=2, and k₂ⱼ=1 for other values of j. n₂₁=n, and n₂ⱼ=1 for other values of j. CI is a distance from the image point of the spectrometer to the common center of curvature of all optical surfaces:

$$CI = \sqrt{( {y}_{o} - {R}_{2} mg {λ}^{2} + {x}_{o}^{2}}$$

φₒ is the object-space telecentricity. φᵢ is the image-space telecentricity. (xₒ, yₒ) are the coordinates of the object point. n is a refractive index of the meniscus lens. m is the diffraction order. g is the groove density of the convex grating. λ is the wavelength. R₁ is a radius of curvature of a front surface of the meniscus lens. R₂ is the radius of curvature of the convex grating. R₃ is a radius of curvature of the primary reflector. R₄ is a radius of curvature of the secondary reflector. R₁ and R₃ are structure parameters determining the object-space telecentricity. R₁ and R₄ are structure parameters determining the image-space telecentricity.

In the present disclosure, a functional relationship between the object-space telecentricity and the structure parameters of the meniscus lens and the primary reflector is as follows:

φₒ=2θ₃ₒ−θ₄ₒ+Δθₒ

Δφₒ is an object-space telecentricity adjustment factor introduced by the meniscus lens:

$$Δ {ϕ}_{0} = {θ}_{1 o} + {θ}_{2 o} - {θ}_{1 o}^{′} - {θ}_{2 o}^{′}$$

θ₁ₒ is an incident angle of an object-space principal ray on the front surface of the meniscus lens:

$${θ}_{1 o} = arcsin ( \frac{CO}{{R}_{1}} )$$

$${θ}_{1 o}^{i}$$

is an emergent angle of the object-space principal ray on the front surface of the meniscus lens:

$${θ}_{1 o}^{′} = arcsin ( \frac{CO}{{nR}_{1}} )$$

θ₂ₒ is an incident angle of the object-space principal ray on a rear surface of the meniscus lens:

$${θ}_{2 o} = arcsin ( \frac{CO}{{nR}_{2}} )$$

$${θ}_{2 o}^{i}$$

is an emergent angle of the object-space principal ray on the rear surface of the meniscus lens:

$${θ}_{2 o}^{′} = arcsin ( \frac{CO}{{R}_{2}} )$$

θ₃ₒ is an incident angle of the object-space principal ray on the primary reflector:

$${θ}_{3 o} = arcsin ( \frac{CO}{{R}_{3}} )$$

θ₄ₒ is an incident angle of the object-space principal ray on the convex grating:

$${θ}_{4 o} = arcsin ( \frac{CO}{{R}_{2}} ) .$$

A functional relationship between the image-space telecentricity and the structure parameters of the meniscus lens and the secondary reflector is as follows:

φᵢ=2θ₃ᵢ−θ₄ᵢ+ΔΔᵢ

Δφᵢ is an image-space telecentricity adjustment factor introduced by the meniscus lens:

$$Δ {ϕ}_{i} = {θ}_{1 i} + {θ}_{2 i} - {θ}_{1 i}^{′} - {θ}_{2 i}^{′}$$

θ₁ᵢ is an emergent angle of an image-space principal ray on the front surface of the meniscus lens:

$${θ}_{1 i} = arcsin ( \frac{CI}{{R}_{1}} )$$

$${θ}_{1 i}^{′}$$

is an incident angle of the image-space principal ray on the front surface of the meniscus lens:

$${θ}_{1 i}^{′} = arcsin ( \frac{CI}{{nR}_{1}} )$$

θ₂ᵢ is an emergent angle of the image-space principal ray on the rear surface of the meniscus lens:

$${θ}_{2 i} = arcsin ( \frac{CI}{{nR}_{2}} )$$

$${θ}_{2 i}^{′}$$

is an incident angle of the image-space principal ray on the rear surface of the meniscus lens:

$${θ}_{2 i}^{′} = arcsin ( \frac{CI}{{R}_{2}} )$$

θ₃ᵢ is an emergent angle of the image-space principal ray on the secondary reflector:

$${θ}_{3 i} = arcsin ( \frac{CI}{{R}_{4}} )$$

θ₄ᵢ is an emergent angle of the image-space principal ray on the convex grating:

$${θ}_{4 i} = arcsin ( \frac{CI}{{R}_{2}} ) .$$

Constraints on a telecentricity deviation and a telecentricity deviation change rate are added to the first surface distribution and the second surface distribution to obtain the initial structure parameters R₁, R₂, R₃, and R₄ of the spectrometer and the off-axis distances yₒ₁ and yₒ₂ of the slits meeting object-space telecentricity and image-space telecentricity requirements. The first surface distribution and the second surface distribution are profiled along a direction of the slits and a direction perpendicular to the slits to obtain profile curves. A profile along the direction of the slits is obtained by taking a cross section of a surface at y=yₒ₁ or y=yₒ₂. A profile along the direction perpendicular to the slits is obtained by taking a cross section of a surface at x=0. Finally, parameters corresponding to curves with flatness less than a flatness threshold are selected from the profile curves as the initial structure parameters of the spectrometer. In the present disclosure, the constraints on the telecentricity deviation and the telecentricity deviation change rate include: the telecentricity deviation of the spectrometer is less than a maximum telecentricity deviation corresponding to an engineering distortion requirement, the telecentricity deviation change rate is 0 when the telecentricity deviation is maximum, and the telecentricity deviation is 0 when the telecentricity deviation change rate is maximum.

In the present disclosure, the maximum telecentricity deviation corresponding to the engineering distortion requirement is as follows:

$${\vert \frac{{y}_{o}}{2} ( {ϕ}_{o} {\vert}_{{( \frac{l}{2} , {y}_{o} , λ )}^{2}} - {ϕ}_{o} {\vert}_{{( o , {y}_{o} , λ )}^{2}} ) - \frac{1}{2} ( {y}_{o} - {R}_{2} * mg λ ) ( {ϕ}_{i} \vert}_{{( \frac{l}{2} , {y}_{o} , λ )}^{2}} - {ϕ}_{i} {\vert}_{{( 0 , {y}_{o} , λ )}^{2}} ) \vert \leq 0.2 d \\ \\ \\ \vert \frac{l}{4} [ ( {ϕ}_{i} {\vert}_{{( \frac{l}{2} , {y}_{o} , {λ}_{n} )}^{2}} - {ϕ}_{i} {\vert}_{{( \frac{l}{2} , {y}_{o} , {λ}_{1} )}^{2 )}} - {ϕ}_{o} {\vert}_{{( \frac{l}{2} , {y}_{o} , {λ}_{n} )}^{2}} - {ϕ}_{o} {\vert}_{{( \frac{l}{2} , {y}_{o} , {λ}_{1} )}^{2 )}} ] \vert \leq 0.2 d$$

φₒ is the object-space telecentricity. φᵢ is the image-space telecentricity. (xₒ, yₒ) are the coordinates of the object point. l is a length of any slit in the slits. (xᵢ, yᵢ) are the coordinates of the image point. R₂ is the radius of curvature of the convex grating. m is the diffraction order. g is the groove density of the convex grating. λ is the wavelength. λ₁-λₙ is an operating wavelength range of the spectrometer. λ₁ is the start wavelength. λₙ is the end wavelength. d is the pixel size of the spectral channel.

In the present disclosure, an initial structure model of the spectrometer with distortion eliminated is first obtained through a double telecentricity path. The initial structure obtained through this method features extremely low distortion and low blur. Because blur is difficult to converge at a time under conditions of a large image plane and large relative aperture, the engineering distortion requirement is used to expand a blur convergence interval and relax a distortion constraint, making the blur quickly converge and ultimately achieving low distortion and a large image plane.

In the implementation method, initial parameters for extending a linear field of view of a conventional spectrometer to a large rectangular field of view are selected as follows:

$$\frac{{l}^{2}}{{R}_{2}^{2}} + \frac{4}{F {\#}^{2}} = 1$$

is used to implement a spectrometer with a long linear field of view.

$$\frac{{l}^{2}}{{R}_{2}^{2}} + 4 {( \frac{1}{F \#} + \frac{h}{{R}_{2}} )}^{2} = 1$$

is used to implement a spectrometer with the large rectangular field of view. l is the length of any slit in the slits. R₂ is the radius of curvature of the convex grating. F # is the F-number of the system. h is a width of the rectangular field of view.

When the large rectangular field of view of the spectrometer is set to two parallel slits, a small-area array detector may be constructed into a large-area array detector for hyperspectral application. A horizontal direction of the two slits is set as follows: The two slits are discontinuously distributed, with discontinuities overlapping each other. An overlap length Lₒ depends on a drift angle θ_{Y} and satisfies Lₒ(min)>Lᵥ·tan(θ_{Y}(max)). A quantity of overlapping pixels is

$${N}_{o} = \frac{{L}_{o}}{d} .$$

A quantity of slit discontinuities in the horizontal direction is

$${N}_{h} = Int ( \frac{{N}_{s}}{{N}_{Dh} - {N}_{o}} ) .$$

A length of each slit discontinuity satisfies Lᵢ≤N_{Dh}·d. Lᵥ is the spacing between the two slits. d is the pixel size of the spectral channel. The drift angle θ_{Y} is an included angle between a satellite flight direction and the direction perpendicular to the slits. Lₒ(min) is a minimum value of Lₒ. θ_{y}(max) is a maximum value of θ_{y}. Nₛ is a total quantity of ground objects in spatial dimension. N_{Dh} is a quantity of pixels of the detector in spatial dimension. A vertical direction of the two slits is set as follows: The spacing between the two slits satisfies Lᵥ=Lᵥ₁+Lᵥ₂+Lᵥ₃. Lᵥ₁=N_{λ}·d. N_{λ} is a quantity of spectral channels. Lᵥ₂=2·d₁+d₂. d₁ is a distance from an outermost effective pixel to an edge of the detector after packaging. d₂ is a minimum required spacing for a detector tiling process. Lᵥ₃=(N_{Dv}−N_{λ})·d. N_{Dv} is a quantity of pixels of the detector in spectral dimension. The small-area array detector is arranged in a staggered pattern. Different rows of the detector are sequentially aligned strictly with images of different wavelengths formed by the slits in image space of the spectrometer.

The large rectangular field of view of the spectrometer is set to two parallel slits with a spacing of Lᵥ. A first slit of the two parallel slits uses a +2^{nd} or −2^{nd} order of the convex grating to perform spectral imaging on wavelengths λ₁ to λₙ. A second slit of the two parallel slits uses a +1^{st} or −1^{st} order of the convex grating to perform spectral imaging on wavelengths 2λ₁ to 2λₙ. A sum of a width Nd of an area array detector in spectral dimension and a mounting spacing ΔL between two detector chips is less than the spacing Lᵥ between the slits and greater than a spectral dispersion width h_{spec} of a single slit, to broaden a spectral range of the spectrometer from λ₁-λₙ to 2λ₁-2λₙ.

The large rectangular field of view of the spectrometer may be set to two parallel slits or a plurality of slits, with a same diffraction order for all slits of the spectrometer. A trajectory and a velocity of a moving target may be obtained through a position of the moving target in different slit fields of view and an elapsed time. If signals of a same target from N slits are superimposed, a signal-to-noise ratio of the target may be increased by a factor of \sqrt{N}. Target detection may be improved in a plurality of aspects through the plurality of slits, but is not limited thereto.

The present disclosure has the following beneficial effects:

As described above, the present disclosure proposes the theoretical model for object- and image-space telecentricity of the spectrometer, and systematically analyzes and optimizes key parameters in complex spectrometer design through the theoretical model for the first time. Under guidance of the theoretical model, the initial structure parameters of the spectrometer are further determined, and an innovative spectrometer featuring a large field of view, high image quality, and extremely low spectral keystone and lateral deviation is successfully designed. With its superior performance, the spectrometer breaks through a technical bottleneck that a conventional spectrometer is difficult to balance between a large field of view and high accuracy, and creates a new path for high-performance spectrometer design.

In addition, the present disclosure adopts an implementation method for rapid design of the spectrometer's initial structure parameters with object- and image-space telecentricity as a core for the first time, and converts a traditional complex aberration optimization problem into a simple parameter solving problem by reconstructing a quantitative relationship between telecentricity design and optical structure parameters. The initial structure obtained through this method features extremely low spectral keystone and lateral deviation, requiring only simple subsequent optimization to meet high-accuracy engineering design requirements. More importantly, this method innovatively resolves a problem that blur and distortion of the spectrometer non-linearly surge as a field of view increases, achieving nearly constant spectral keystone and lateral deviation in a large field of view. This breakthrough innovation overcomes traditional technical limitations on a length and width of the field of view of the spectrometer, provides theoretical support for engineering application of a wide-spectrum and wide-swath spaceborne hyperspectral imager, and lays a foundation for development of spaceborne wide-spectrum and wide-swath hyperspectral imaging.

In addition, the solution provided by the present disclosure can resolve a technical problem of designing a spectrometer with a rectangular field of view under conditions of a small F-number, low distortion, and high image quality. A spectrometer with a large rectangular field of view provides a feasible scheme for application of a small-area array detector with tiling in a staggered pattern in a spaceborne wide-swath hyperspectral payload. This technical breakthrough not only significantly improves engineering efficiency of a spaceborne hyperspectral spectrometer, but also successfully shortens a research and development period of a spaceborne wide-spectrum wide-swath hyperspectral payload by 5 to 10 years. It accelerates implementation of an ultra-wide-swath, high-quantitative, and high-accuracy spaceborne hyperspectral remote sensing technology, and provides important technical guarantee for future in-orbit remote sensing detection and resource monitoring. Further, the large rectangular field of view of the spectrometer is set to two parallel slits or a plurality of slits such that a spectral range can be broadened several times under different grating diffraction orders, a trajectory and a velocity of a moving target can be obtained under a same grating diffraction order, or a signal-to-noise ratio of a static target can be improved several times. The solution provided by the present disclosure enables a leap forward in spectrometer design, from theoretical innovation to engineering application. Its achievements hold significant scientific value and engineering significance, supporting in-orbit application of spaceborne wide-spectrum wide-swath hyperspectral cameras and significantly advancing technological progress in fields such as remote sensing, environmental monitoring, and resource detection.

### BRIEF DESCRIPTION OF THE DRAWINGS

FIG. 1 is a schematic diagram of an application scenario according to the present disclosure;

FIG. 2 is an example diagram of a linear field of view, low distortion, a large image plane achieved by a spectrometer and an object- and image-space telecentricity model according to the present disclosure;

FIG. 3 is an example diagram of a rectangular field of view, low distortion, a large image plane achieved by a spectrometer and an object- and image-space telecentricity model according to the present disclosure;

FIG. 4 is an example diagram of a spectral effect achieved by extending a rectangular field of view of a spectrometer and an object- and image-space telecentricity model according to the present disclosure;

FIG. 5 is an example diagram of parameters of a theoretical model for object- and image-space telecentricity of a spectrometer according to the present disclosure;

FIG. 6 is a principle diagram of multi-slit parallel imaging according to the present disclosure;

FIG. 7 is a principle diagram of trajectory fitting and velocity calculation according to the present disclosure;

FIG. 8(a) is an example diagram of a position of a single slit according to the present disclosure;

FIG. 8(b) is an example diagram of positions of a plurality of slits according to the present disclosure;

FIG. 9(a), FIG. 9(b), FIG. 9(c), FIG. 9(d), FIG. 10(a), FIG. 10(b), FIG. 10(c), FIG. 10(d), FIG. 11(a), FIG. 11(b), FIG. 11(c), and FIG. 11(d) are example diagrams of simulated changes in telecentricity with a field of view for materials with different refractive indexes according to the present disclosure;

FIG. 12(a) is an example diagram of a fitted three-dimensional distribution of object-space telecentricity with respect to a rectangular field of view at a start wavelength according to the present disclosure;

FIG. 12(b) is an example diagram of a fitted three-dimensional distribution of image-space telecentricity with respect to a rectangular field of view at a start wavelength according to the present disclosure;

FIG. 12(c) is an example diagram of a fitted three-dimensional distribution of object-space telecentricity with respect to a rectangular field of view at a center wavelength according to the present disclosure;

FIG. 12(d) is an example diagram of a fitted three-dimensional distribution of image-space telecentricity with respect to a rectangular field of view at a center wavelength according to the present disclosure;

FIG. 12(e) is an example diagram of a fitted three-dimensional distribution of object-space telecentricity with respect to a rectangular field of view at an end wavelength according to the present disclosure;

FIG. 12(f) is an example diagram of a fitted three-dimensional distribution of image-space telecentricity with respect to a rectangular field of view at an end wavelength according to the present disclosure;

FIG. 13(a) is an example diagram of a simulated change in object-space telecentricity of a slit 1 in two slits with a slit length according to the present disclosure;

FIG. 13(b) is an example diagram of a simulated change in image-space telecentricity of a slit 1 in two slits with a slit length according to the present disclosure;

FIG. 13(c) is an example diagram of a simulated change in spectral smile of a slit 1 in two slits with a slit length according to the present disclosure;

FIG. 13(d) is an example diagram of a simulated change in spectral keystone of a slit 1 in two slits with a slit length according to the present disclosure;

FIG. 13(e) is an example diagram of a simulated change in astigmatism of a slit 1 in two slits with a slit length according to the present disclosure;

FIG. 13(f) is an example diagram of a simulated change in astigmatism, after flattening a sagittal field curvature, of a slit 1 in two slits with a slit length according to the present disclosure;

FIG. 14(a) is an example diagram of a simulated change in object-space telecentricity of a slit 2 in two slits with a slit length according to the present disclosure;

FIG. 14(b) is an example diagram of a simulated change in image-space telecentricity of a slit 2 in two slits with a slit length according to the present disclosure;

FIG. 14(c) is an example diagram of a simulated change in spectral smile of a slit 2 in two slits with a slit length according to the present disclosure;

FIG. 14(d) is an example diagram of a simulated change in spectral keystone of a slit 2 in two slits with a slit length according to the present disclosure;

FIG. 14(e) is an example diagram of a simulated change in astigmatism of a slit 2 in two slits with a slit length according to the present disclosure;

FIG. 14(f) is an example diagram of a simulated change in astigmatism, after flattening a sagittal field curvature, of a slit 2 in two slits with a slit length according to the present disclosure;

FIG. 15 is a flowchart of obtaining an initial structure model of a spectrometer with low distortion and a large image plane according to the present disclosure;

FIG. 16 is an example diagram of a curve obtained with flatness less than a flatness threshold according to the present disclosure;

FIG. 17(a) is a diagram of a first surface distribution according to the present disclosure;

FIG. 17(b) is a diagram of a profile curve obtained by profiling a first surface distribution along a direction perpendicular to slits according to the present disclosure;

FIG. 17(c) is a diagram of a profile curve obtained by profiling a first surface distribution along a direction of a slit 1 according to the present disclosure;

FIG. 17(d) is a diagram of a profile curve obtained by profiling a first surface distribution along a direction of a slit 2 according to the present disclosure;

FIG. 18(a) is a diagram of a second surface distribution according to the present disclosure;

FIG. 18(b) is a diagram of a profile curve obtained by profiling a second surface distribution along a direction perpendicular to slits according to the present disclosure;

FIG. 18(c) is a diagram of a profile curve obtained by profiling a second surface distribution along a direction of a slit 1 according to the present disclosure;

FIG. 18(d) is a diagram of a profile curve obtained by profiling a second surface distribution along a direction of a slit 2 according to the present disclosure;

FIG. 19 and FIG. 20 are respectively spot diagrams of single-slit and double-slit spectrometers according to the present disclosure;

FIG. 21(a) is an example diagram in which non-linearly surging blur becomes nearly constant according to the present disclosure; and

FIG. 21(b) is an example diagram in which non-linearly surging distortion becomes nearly constant according to the present disclosure.

### DETAILED DESCRIPTION

The implementations of the present disclosure are described below through specific examples, and those skilled in the art can easily understand other advantages and effects of the present disclosure from content disclosed in this specification. The present disclosure can also be implemented or applied through other different specific implementations. Based on different viewpoints and applications, various modifications or amendments can be made to various details of this specification without departing from the spirit of the present disclosure. It should be noted that features in the following content may be combined with each other provided that no conflict occurs.

It should be noted that the drawings provided in the following content merely illustrate basic concepts of the present disclosure schematically. Therefore, the drawings only show components related to the present disclosure rather than being drawn according to quantities, shapes, and sizes of components in actual implementation, patterns, quantities, and proportions of components in actual implementation may be changed randomly, and a component layout may be more complex.

Before the present disclosure is described in further detail, nouns and terms used in the present disclosure are described. The nouns and terms used in the present disclosure are explained as follows:
<1> Telecentricity: A principal ray is parallel to an optical axis upon incidence or emergence.
<2> Object-space telecentricity: When an aperture stop is located on a rear focal plane of an optical system, an incident pupil is at infinity, and a principal ray enters the optical system parallel to an optical axis or perpendicular to an object plane.
<3> Image-space telecentricity: When an aperture stop is located on a front focal plane of an optical system, an emergent pupil is at infinity, and a principal ray is parallel to an optical axis or perpendicular to an image plane upon emergence.
<4> Telecentricity deviation: It is a degree to which a ray deviates from telecentricity, represented by a deviation angle between a principal ray of an imaging beam and a direction of an optical axis.
<5> Telecentricity deviation change rate: It is a rate at which a telecentricity deviation changes with a field of view.

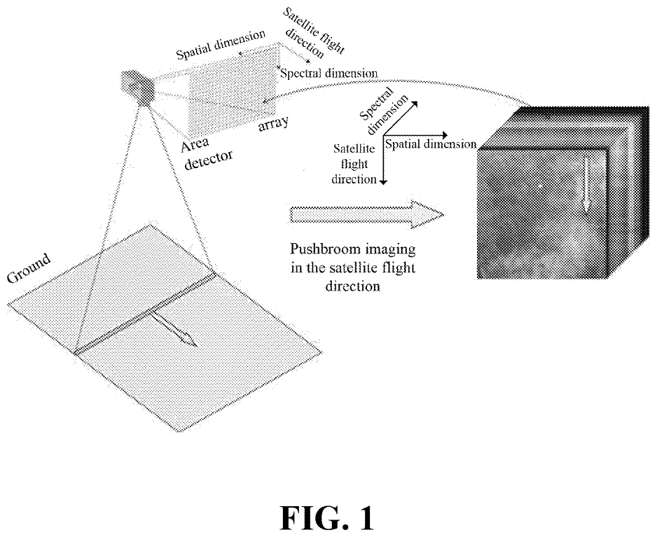

As one of core optical components in a hyperspectral imaging technology, a spectrometer has been widely used in numerous scenarios. (The term “hyperspectral imaging technology” has a recognized and exact meaning in the technical field of remote sensing: The hyperspectral imaging technology can obtain hundreds of continuous and fine spectra of targets within a wide spectral range while acquiring geometric, radiometric, and spectral information of the targets to form an image cube, achieving “fingerprint” identification of ground objects. (Liu Yinnian. Current Status and Development of Hyperspectral Imaging Remote Sensing Payload Technology[J]. Journal of Remote Sensing, 2021, 25(01): 439-459.)) For example, in a spaceborne hyperspectral imaging scenario shown in FIG. 1, a spectrometer may be mounted on a satellite platform to detect fine spectral and spatial information of ground targets from space. The present disclosure provides an implementation method of a hyperspectral imaging spectrometer with low distortion, a large image plane, and object- and image-space telecentricity. It should be noted that low distortion and a large image plane need to be simultaneously achieved to ensure high-quality, wide-spectrum, and wide-swath imaging (generally, a wavelength range exceeding 0.45-2.5 m may be considered wide-spectrum; and a swath width reaching 60 km may be considered wide-swath). At present, a maximum image plane of in-orbit hyperspectral imaging spectrometers worldwide has a spatial dimension of approximately 30-40 mm and a spectral dimension of less than 20 mm, with distortion less than 0.2 pixels. Specific values of the large image plane and low distortion may be determined based on an actual requirements. For example, in some implementations, an image plane may be considered large when its diagonal reaches 50 mm, and distortion may be considered low when it is less than or equal to 0.2 pixels. For another example, in some implementations, an image plane may be considered large when its diagonal reaches 40 mm, and distortion may be considered low when it is less than or equal to 0.3 pixels. However, the present disclosure is not limited thereto.

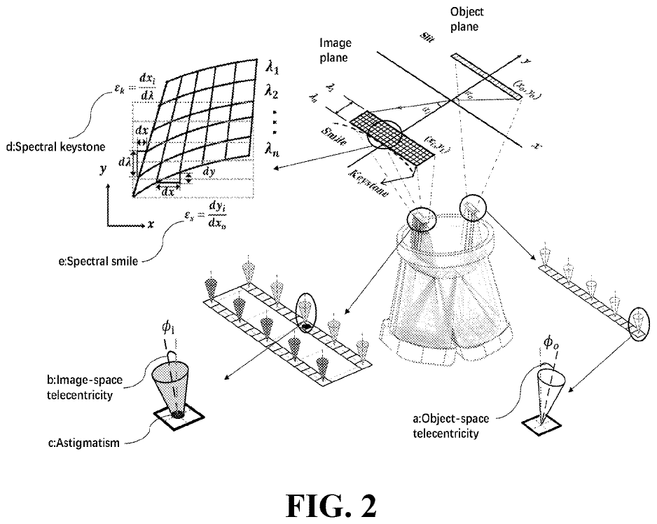

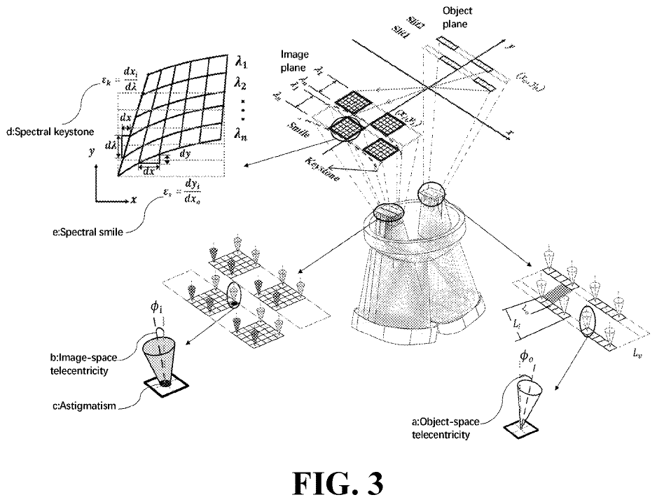

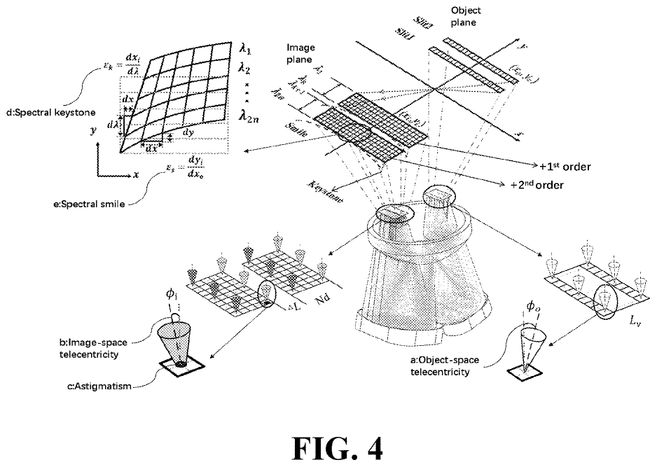

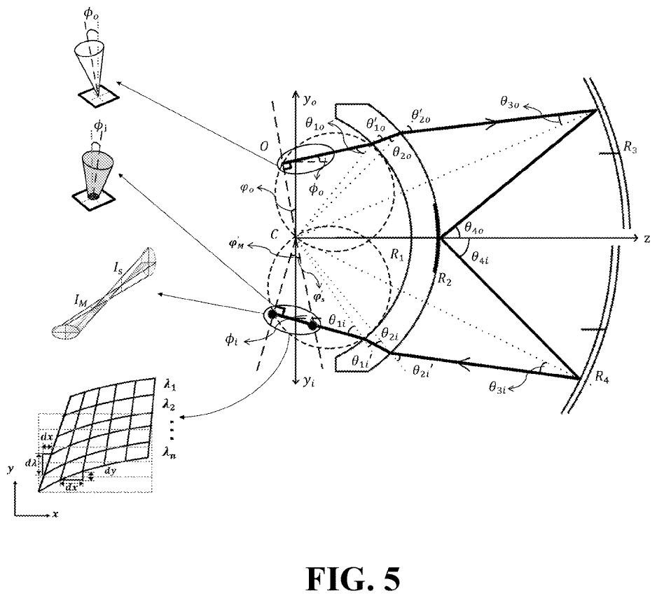

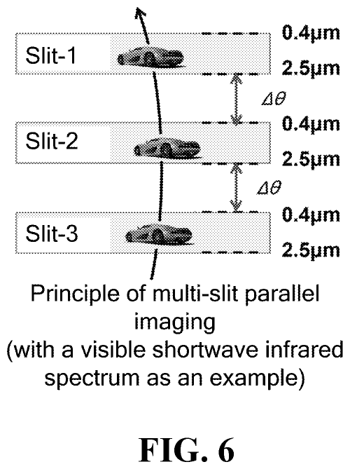

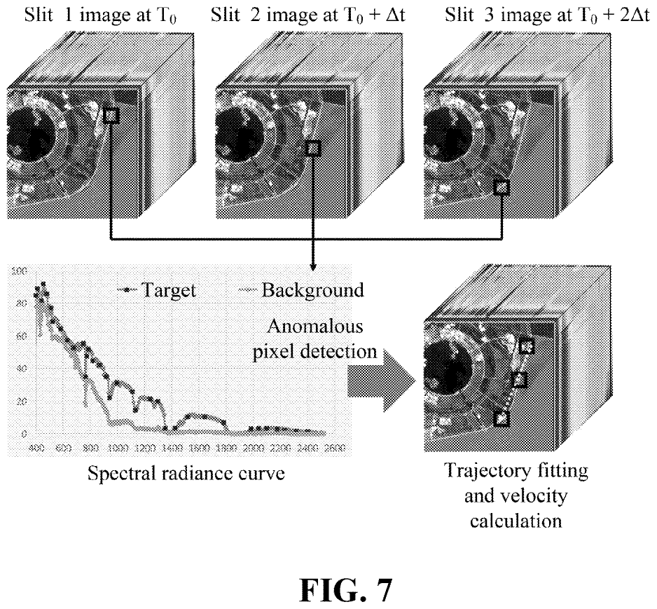

Refer to FIG. 2 to FIG. 7. As shown in FIG. 2, FIG. 3, FIG. 4, and FIG. 5, the spectrometer includes a field stop with slits, a meniscus lens, a primary reflector, a secondary reflector, and a convex grating. A theoretical model for object- and image-space telecentricity of the spectrometer is composed of three sub-models: “spectral smile-telecentricity”, “spectral keystone-telecentricity”, and “astigmatism-telecentricity”. The “spectral smile-telecentricity” model describes a mapping relationship of e with a and b. The “spectral keystone-telecentricity” model describes a mapping relationship of d with a and b. The “astigmatism-telecentricity” model describes a mapping relationship of c with a and b. As shown in FIG. 2, the spectrometer may achieve an ultra-long single-slit field of view. As shown in FIG. 3, the large image plane of the spectrometer may be used for tiling of a small-area array detector in a staggered pattern. As shown in FIG. 4, the large image plane of the spectrometer may be used for multi-order spectral imaging, to broaden a spectral range. It should be noted that the spectrometer shown in FIG. 2 to FIG. 4 has a single slit or double slits, but the present disclosure is not limited thereto. In some other implementations, there may alternatively be two or more slits. FIG. 5 is an example diagram of a theoretical model for object- and image-space telecentricity of a spectrometer and parameters thereof according to the present disclosure. FIG. 6 is a principle diagram of multi-slit parallel imaging according to the present disclosure. FIG. 7 is a principle diagram of trajectory fitting and velocity calculation according to the present disclosure. A horizontal coordinate is a wavelength, measured in nm. A vertical coordinate is a spectral radiance, measured in W/m²/sr/μm.

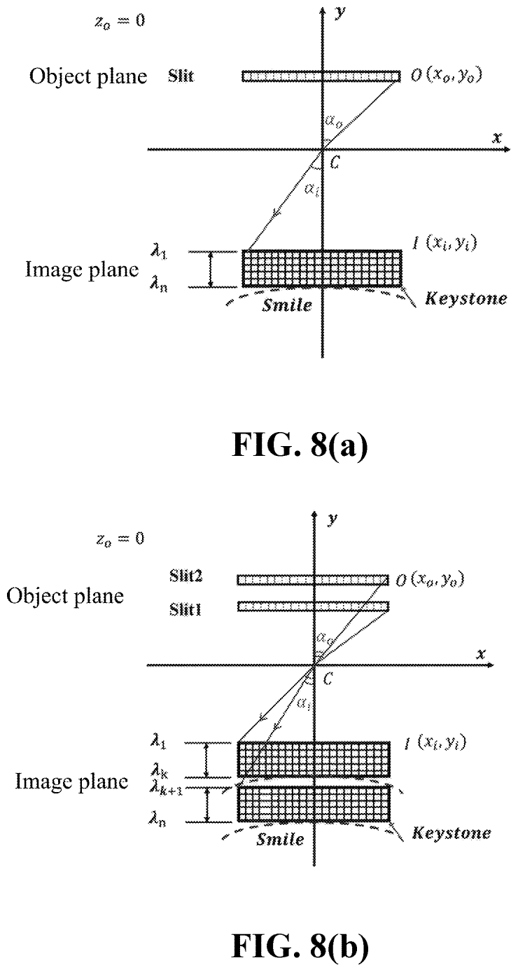

As shown in FIG. 8(a) and FIG. 8(b), a condition of flattening a sagittal field curvature is set based on the “astigmatism-telecentricity” model. The slit is located on a plane XCY perpendicular to an optical axis and passing through a common center of curvature of all optical surfaces (the slit is parallel to an x-axis, a zₒ coordinate of any point on the slit is zero, zₒ is a Z coordinate of an object point, and the slit is at a distance of yₒ from the common center of curvature C). This can ensure that the spectrometer achieves low astigmatism and a flattened field curvature.

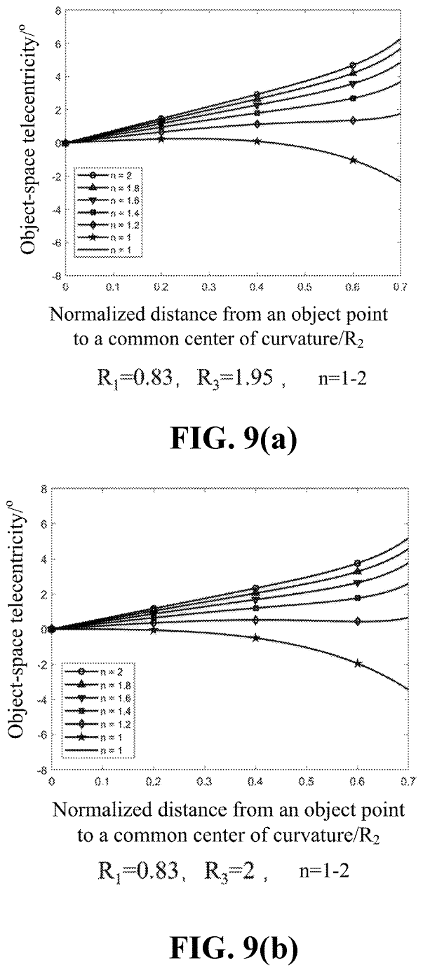

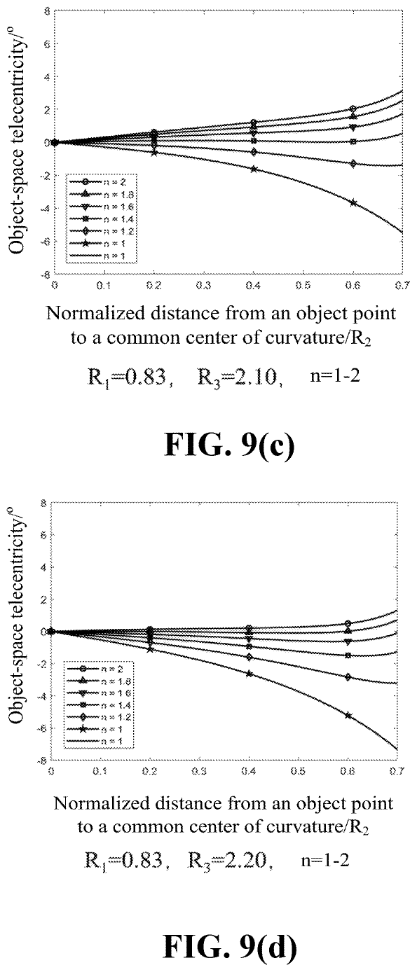

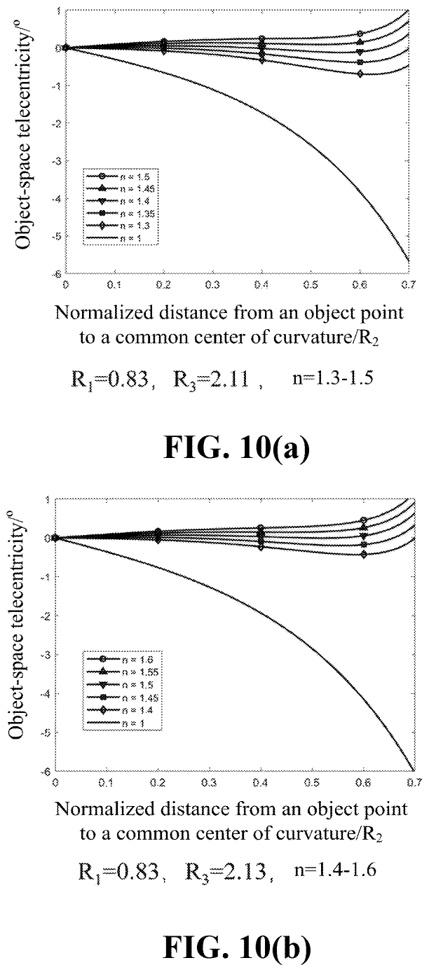

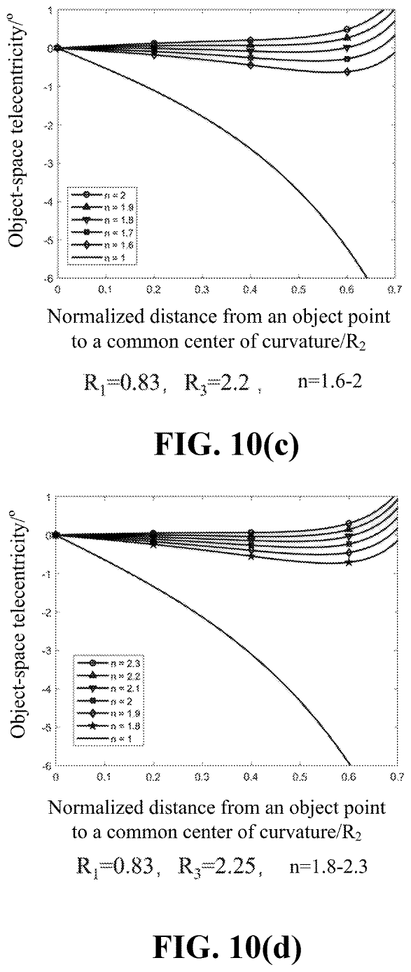

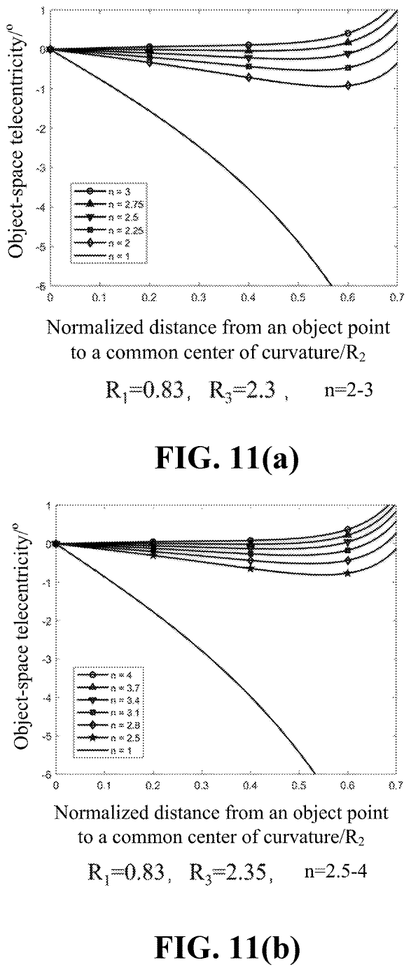

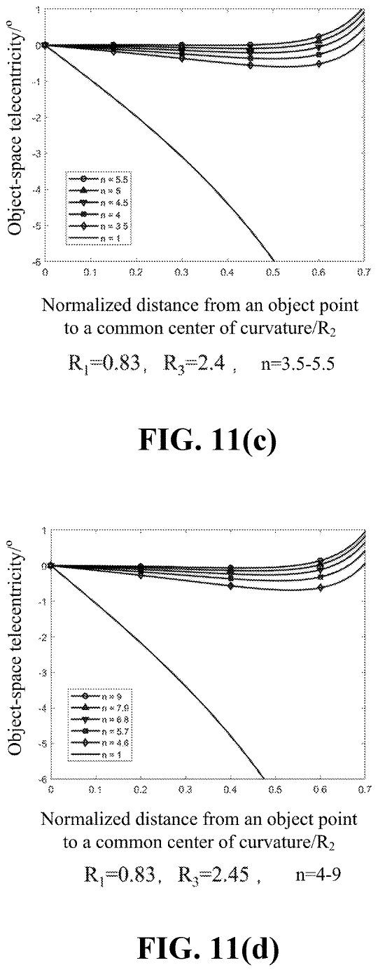

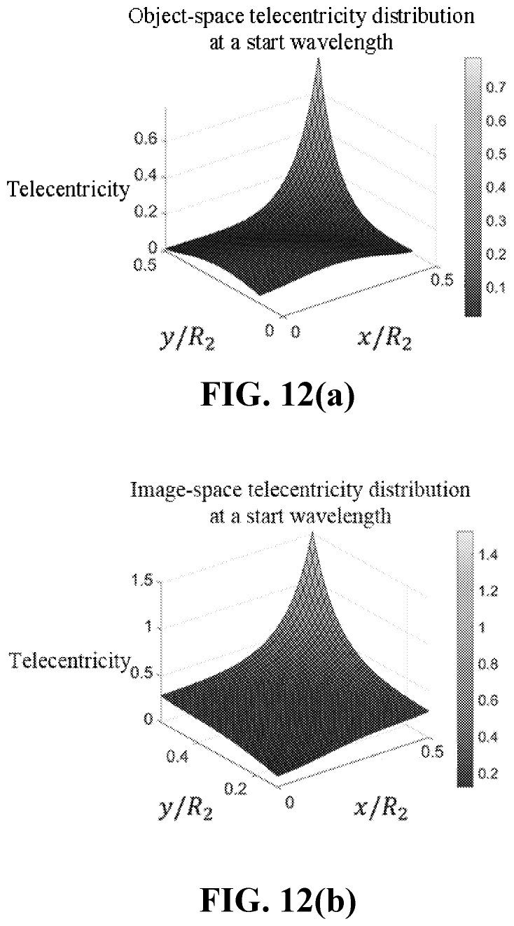

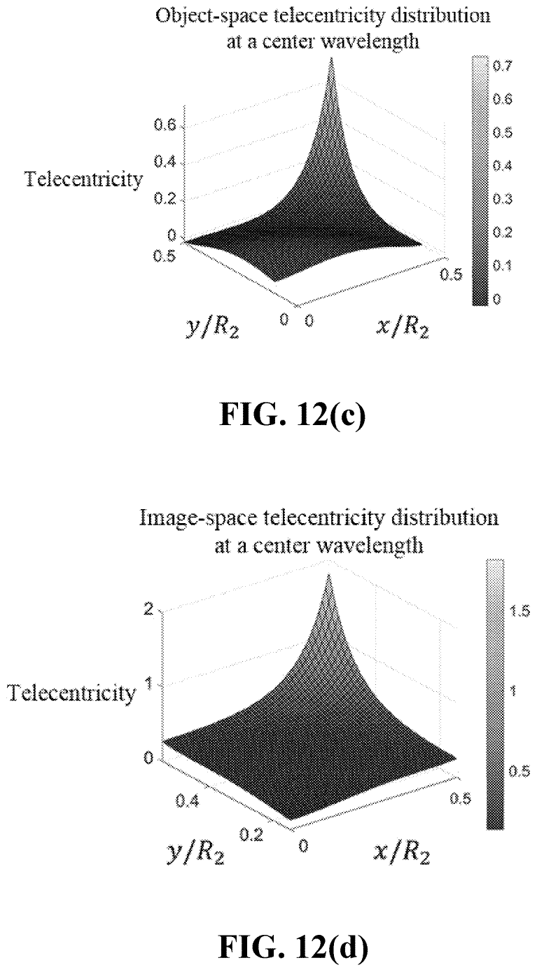

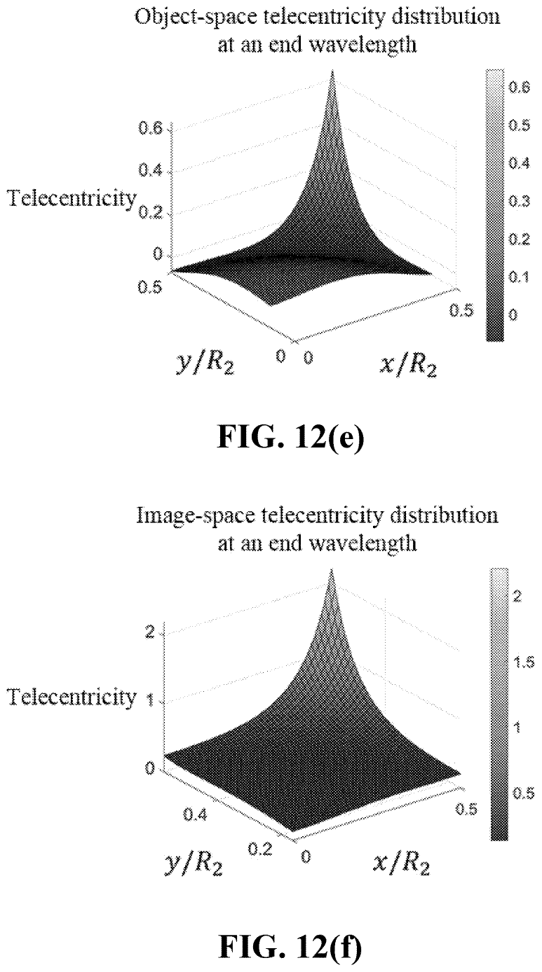

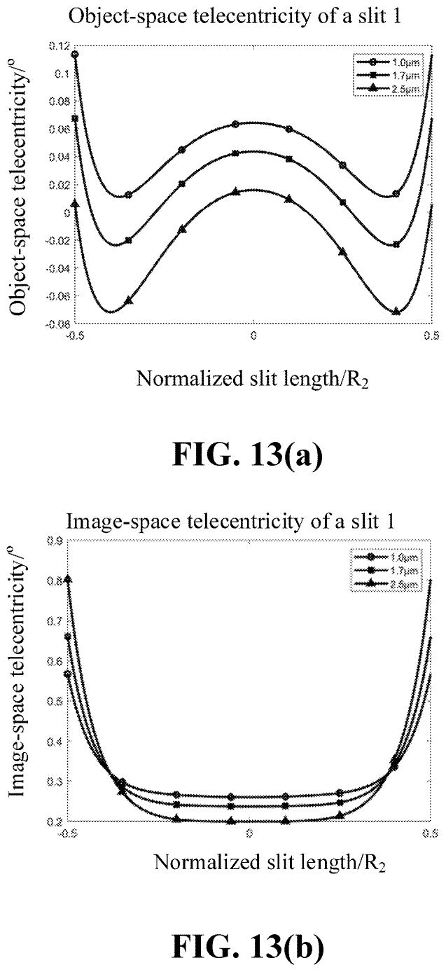

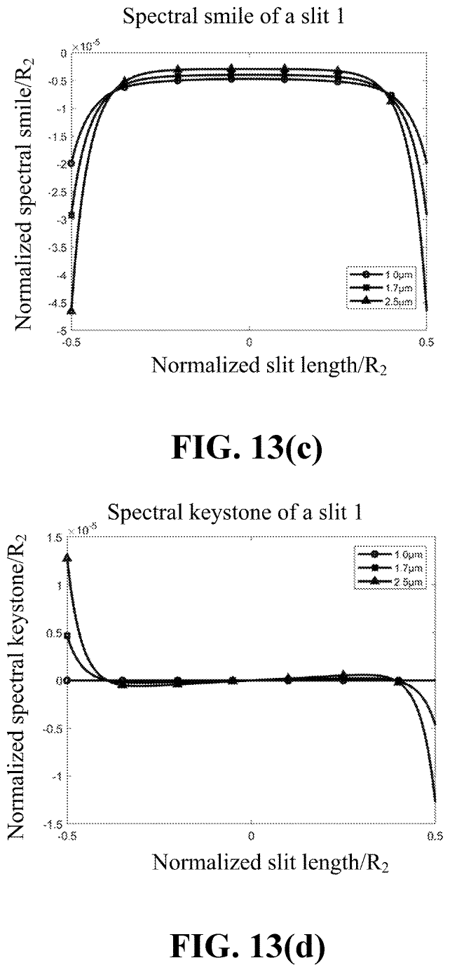

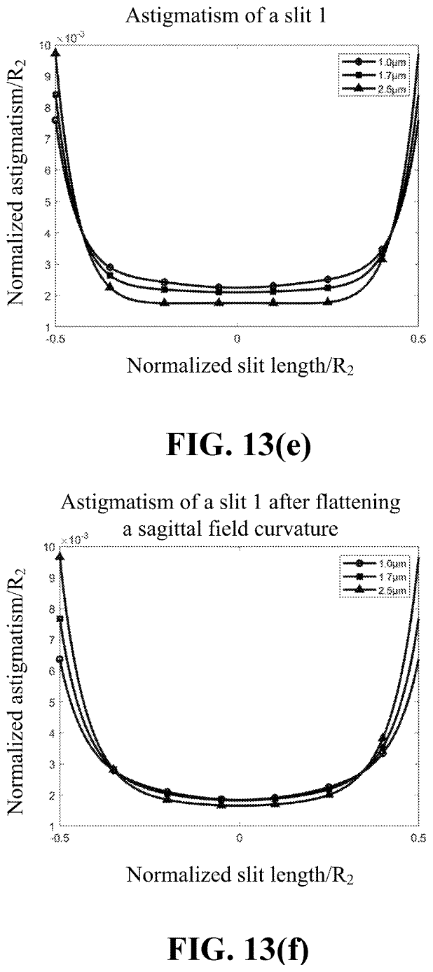

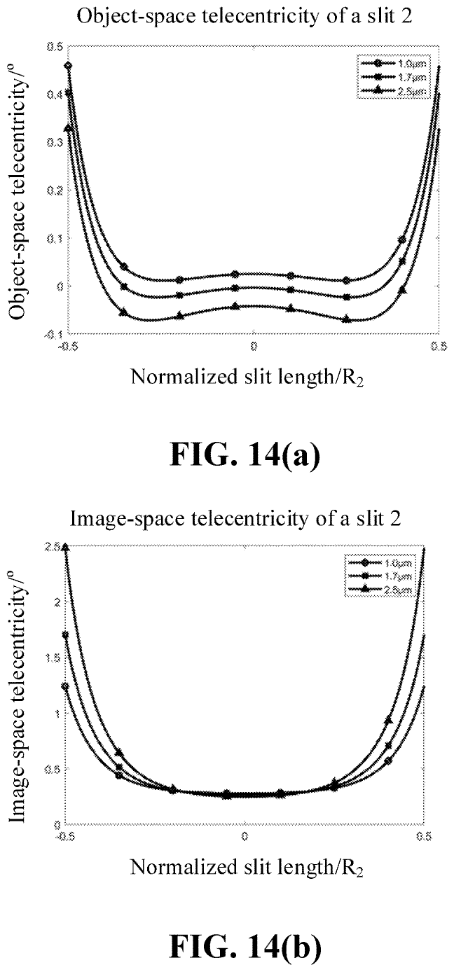

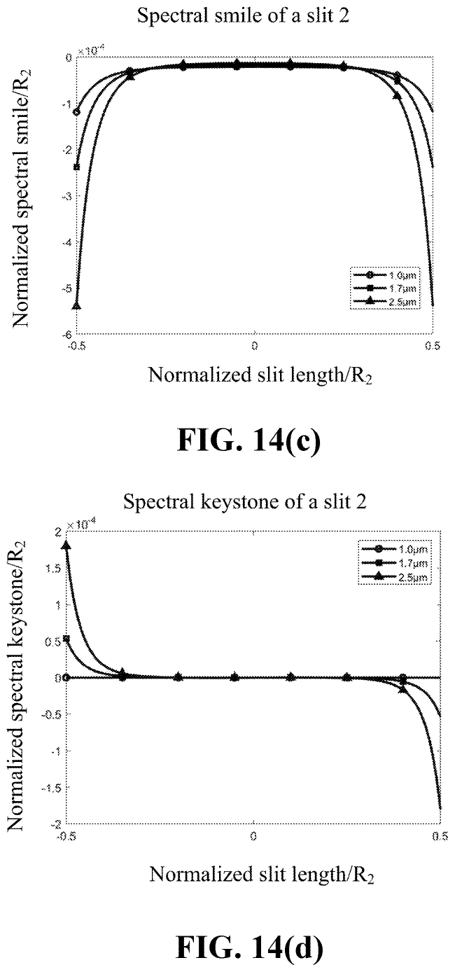

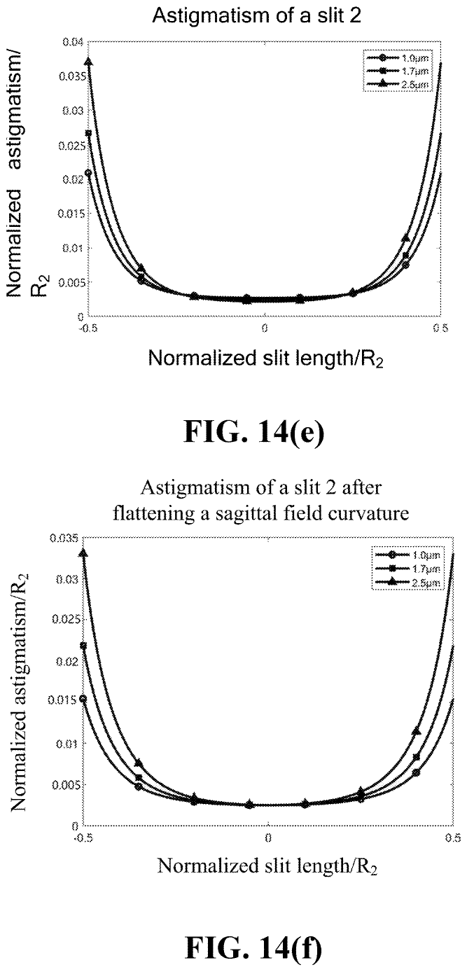

In the present disclosure, a design idea of the spectrometer includes: exploring changes in object-space telecentricity of the spectrometer with a field of view for materials with different refractive indexes, as shown in FIG. 9(a) to FIG. 11(d). As a radius of the reflector evolves from 1.95 and 2 to 2.45 times a radius of the convex grating, a refractive index greater than 1.3 enables the spectrometer to have a larger telecentricity range than a refractive index of 1 (a conventional Offner spectrometer), making the spectrometer applicable to an extremely wide spectral range from ultraviolet to very long wave. After a corrective lens is introduced into the conventional Offner spectrometer, changes in object- and image-space telecentricity from a start wavelength 1=1.0 m to an end wavelength λₙ=2.5 m are observed. The introduction of the corrective lens enables a larger range of object- and image-space telecentricity to be maintained in a direction of the slit. When combined with an appropriate reflector structure, it further significantly reduces chromatic aberration due to diffraction while maintaining object- and image-space telecentricity in a matrix field of view. FIG. 12(a) to FIG. 12(f) show three-dimensional distribution surfaces of object- and image-space telecentricity with respect to a rectangular field of view when the spectrometer has structure parameters R₁=0.827, R₃=2.12, and R₄=2.10, a start wavelength is 1.0 m, a center wavelength is 1.7 m, and an end wavelength is 2.5 m. The telecentricity range of the spectrometer is maintained within one convex grating radius. Beyond this limit, the telecentricity of the spectrometer surges non-linearly with the field of view. FIG. 13(a) to FIG. 14(f) show rules of non-linear changes in distortion and astigmatism with a field of view from a perspective of telecentricity calculation for the first time. Analysis indicates that a purpose of a next design step is to achieve object- and image-space telecentricity in a large field of view.

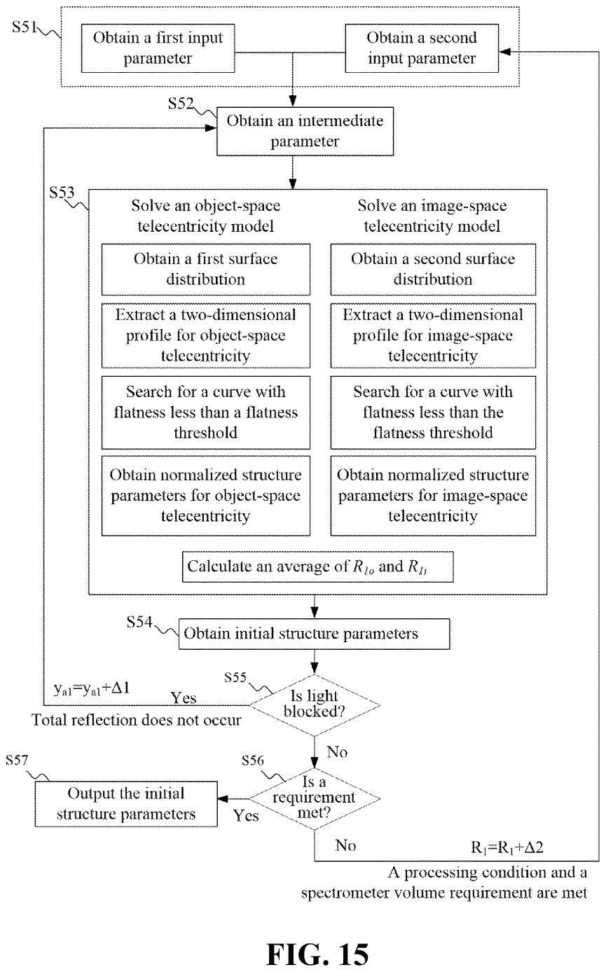

FIG. 15 is a flowchart of an implementation method of a spectrometer with low distortion, a large image plane, and object- and image-space telecentricity according to the present disclosure. In the present disclosure, initial structure parameters of the spectrometer include R₁, R₂, R₃, R₄, yₒ₁, yₒ₂, l, and F #. As shown in FIG. 15, when there are two slits, a process of determining the initial structure parameters includes the following steps S51 to S57 performed by a computer device or a processor.

S51: Obtain a first input parameter and a second input parameter. The first input parameter is a fixed value throughout the process, and the second input parameter is a variable value.

The first input parameter includes a slit length l, an F-number F # of a system, an order m of a convex grating, a spectral resolution Δλ, a pixel size d of a spectral channel, and a spacing Lᵥ between the two slits. These parameters may be set based on an actual requirement or experience. Their specific values are not limited in the present disclosure.

The second input parameter includes a radius of curvature R₂ of the convex grating, a groove density g of the convex grating, and a lens refractive index n(λ) at an operating wavelength. R₂ and g may be selected by considering both a volume envelope of the spectrometer and diffraction efficiency of the convex grating, and satisfy the following conditions:

$${R}_{2} \geq \sqrt{{( \frac{1}{F \#} \vert {R}_{2} \vert + {L}_{v} )}^{2} + {( \frac{l}{2} )}^{2}}$$

$${mgR}_{2} = \frac{d}{Δ λ}$$

S52: Obtain an intermediate parameter based on the first input parameter and the second input parameter. The intermediate parameter includes an off-axis distance yₒ₁ of a first slit of the two parallel slits and an off-axis distance yₒ₂ of a second slit of the two parallel slits. yₒ₁ and yₒ₂ satisfy the following conditions:

$${y}_{o1} > \frac{1}{F \#} \vert {R}_{2} \vert$$

$${y}_{o2} = {y}_{o1} + {L}_{v}$$

S53: Solve an object-space telecentricity model and an image-space telecentricity model to obtain normalized structure parameters (R₁ₒ and R₃) for object-space telecentricity and normalized structure parameters (R₁ᵢ, and R₄) for image-space telecentricity. An average of R₁ₒ and R₁ᵢ is calculated to obtain R₁. R₁ₒ is a value of R₁ obtained for object-space telecentricity, and R₁ᵢ, is a value of R₁ obtained for image-space telecentricity.

A process of solving the image-space and image-space telecentricity models may include:

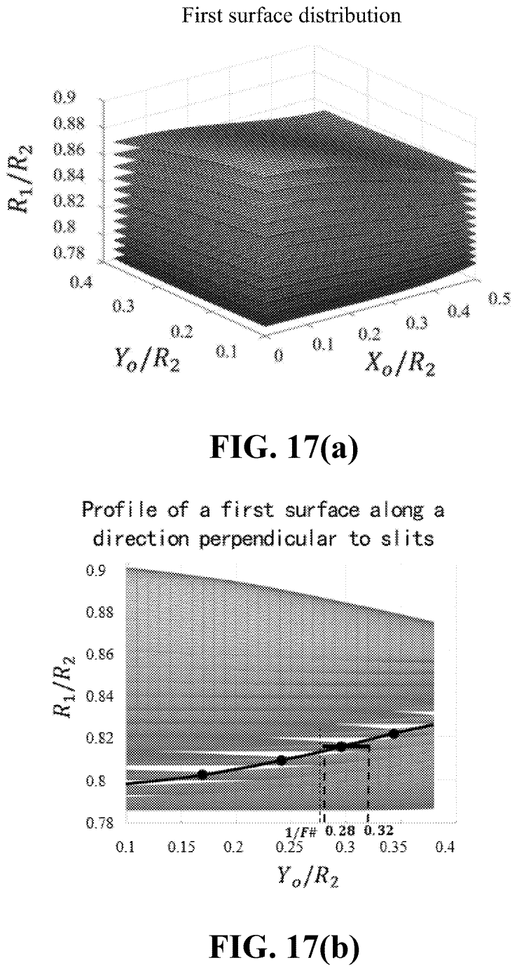

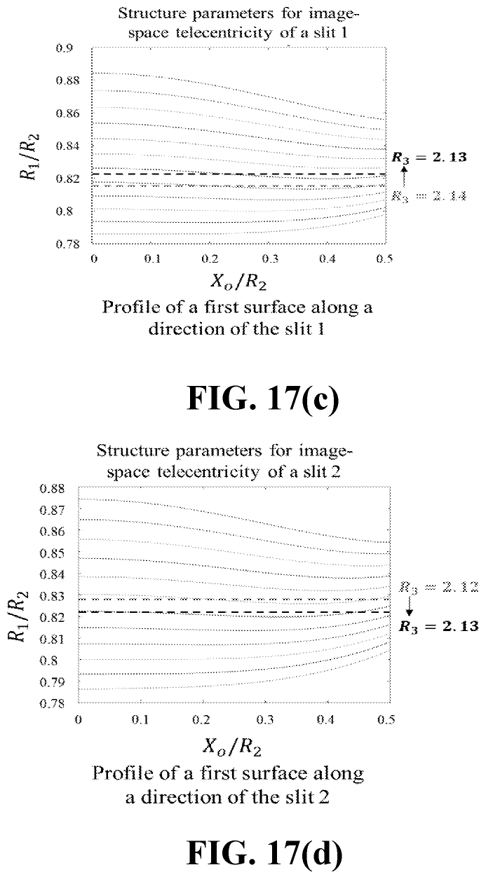

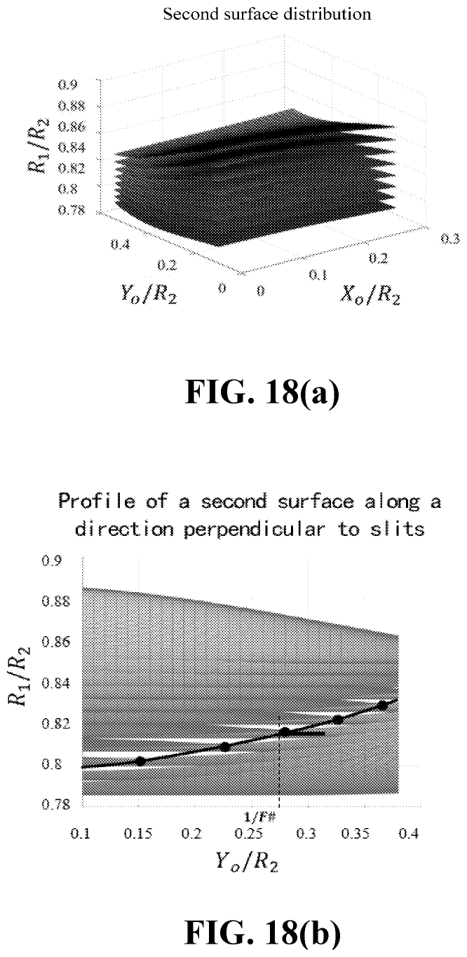

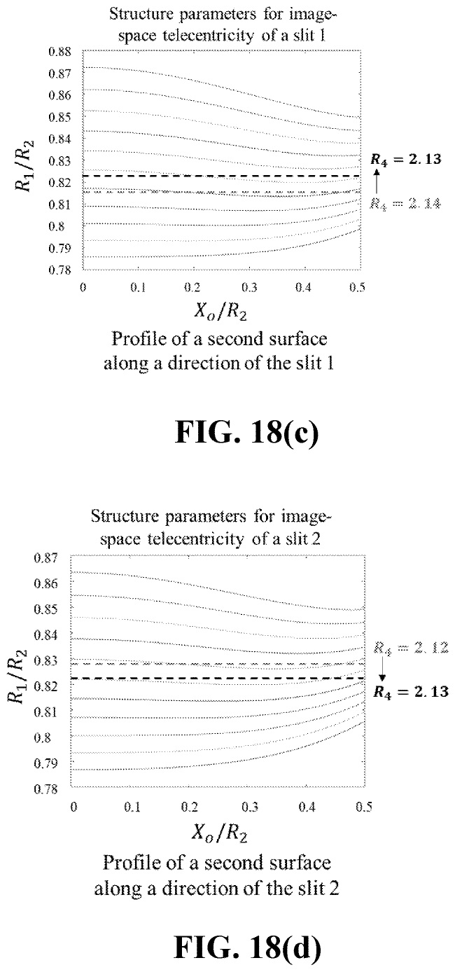

Refer to FIG. 17(a) to FIG. 18(d). First, based on the foregoing theoretical model for object- and image-space telecentricity of the spectrometer, when object- and image-space telecentricity of the spectrometer is achieved to eliminate distortion of the spectrometer in a large field of view, a first surface distribution and a second surface distribution are obtained. The first surface distribution is a surface distribution of structure parameters of a meniscus lens and a primary reflector with respect to a two-dimensional rectangular field of view when object-space telecentricity is achieved. The second surface distribution is a surface distribution of structure parameters of the meniscus lens and a secondary reflector with respect to the two-dimensional rectangular field of view when image-space telecentricity is achieved.

Then, under constraints on a telecentricity deviation and a telecentricity deviation change rate, the first surface distribution and the second surface distribution are respectively profiled along a direction of the slits and a direction perpendicular to the slits to obtain profile curves.

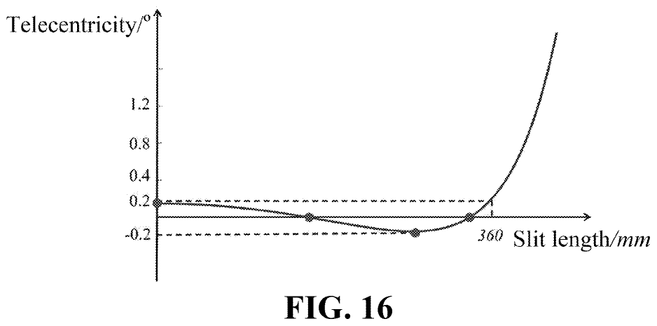

Finally, the profile curve for object-space telecentricity is searched for a curve with flatness less than a flatness threshold in a design field of view, and its parameters are obtained as the normalized structure parameters (R₁ₒ and R₃) for object-space telecentricity. The design field of view may be determined based on an actual requirement. The profile curve for image-space telecentricity is searched for a curve with flatness less than the flatness threshold in the design field of view, and its parameters are obtained as the normalized structure parameters (R₁ᵢ and R₄) for image-space telecentricity. FIG. 16 is an example diagram of a curve selected according to the present disclosure.

S54: Obtain the initial structure parameters, including R₁, R₂, R₃, R₄, yₒ₁, yₒ₂, l, and F #.

S55: If an initial structure corresponding to the initial structure parameters blocks light, adjust yₒ₁ and return to step S52. Otherwise, perform step S56. A method for adjusting yₒ₁ is, for example, setting yₒ₁=yₒ₁+Δ1. In addition, adjusted yₒ₁ should meet a requirement that total reflection does not occur. Δ1 is an adjustment step. Its specific value may be set based on an actual requirement.

S56: Determine whether the initial structure meets a spectral detection requirement for engineering application. If the requirement is met, perform step S57. Otherwise, adjust R₂ and return to step S51. A method for adjusting R₂ is, for example, setting R₂=R₂+Δ₂. In addition, adjusted R₂ should satisfy both a processing condition and a volume requirement for the spectrometer. Δ₂ is an adjustment step. Its specific value may be set based on an actual requirement.

S57: If determining in S55 that light is not blocked and in S56 that the spectral detection requirement for engineering application is met, output the initial structure parameters and establish the initial structure of the spectrometer.

After the initial structure parameters of the spectrometer are obtained, a distortion requirement may be appropriately relaxed to balance between distortion and image quality, thereby optimizing the structure of the spectrometer to achieve best performance required for engineering.

It should be noted that when there is a single slit, a process of obtaining the initial structure parameters of the spectrometer is similar to that shown in FIG. 15, except that yₒ₂ is not involved in the process. For brevity, details are not described herein again.

In the present disclosure, the foregoing theoretical model includes the “spectral smile-telecentricity” model of the spectrometer, the “spectral keystone-telecentricity” model of the spectrometer, and the “astigmatism-telecentricity” model of the spectrometer.

The “spectral smile-telecentricity” model of the spectrometer may be expressed as follows:

$${ε}_{s} = \frac{d {y}_{i}}{d {x}_{o}} = [ {y}_{0} tan {ϕ}_{o} \cdot \frac{d {ϕ}_{o}}{d {x}_{o}} + ( \frac{{R}_{g} \cdot mg λ}{cos {ϕ}_{o}} - {y}_{o} ) \cdot tan {ϕ}_{i} \cdot \frac{d {ϕ}_{i}}{d {x}_{o}} ] \cdot \frac{cos {ϕ}_{o}}{cos {ϕ}_{i}}$$

φₒ is the object-space telecentricity. φᵢ is the image-space telecentricity. (xₒ, yₒ) are coordinates of an object point. (xᵢ, yᵢ) are coordinates of an image point. R₂ is the radius of curvature of the convex grating. m is a diffraction order. g is the groove density of the convex grating. λ is a wavelength.

The “spectral keystone-telecentricity” model of the spectrometer may be expressed as follows:

$${ε}_{k} = \frac{d {x}_{i}}{d λ} = [ tan {ϕ}_{o} \frac{d {ϕ}_{o}}{d λ} - tan {ϕ}_{i} \cdot \frac{d {ϕ}_{i}}{d λ} ] \cdot {x}_{o} \cdot \frac{cos {ϕ}_{o}}{cos {ϕ}_{i}}$$

The “astigmatism-telecentricity” model of the spectrometer may be expressed as follows:

$${ε}_{a} = \frac{sin {α}_{o}}{sin {α}_{i}} \cdot CO \cdot tan [ {ϕ}_{i} + arctan ( \frac{sin {α}_{i}}{sin {α}_{o}} \cdot tan {ϕ}_{o} ) ]$$

εₛ is a value of spectral smile. εₖ is a value of spectral keystone. εₐ is a value of astigmatism. αₒ is an incident azimuth angle of a principal ray of the spectrometer. αᵢ is an emergent azimuth angle of the principal ray of the spectrometer. φₒ is the object-space telecentricity. φᵢ is the image-space telecentricity. CO is a distance from the object point of the spectrometer to the common center of curvature of all optical surfaces.

Based on the foregoing “spectral smile-telecentricity” model, “spectral keystone-telecentricity” model, and “astigmatism-telecentricity” model, high-quantitative implementation parameters of the spectrometer featuring a large field of view, high image quality, low spectral smile, and low spectral lateral deviation may be determined as follows:

$$\{ \begin{matrix}tan {ϕ}_{o} \cdot \frac{d {ϕ}_{o}}{d {x}_{o}} {\vert}_{{x}_{o} = {x}_{{o}_{1 ∼ ∞}}} = tan {ϕ}_{i} \cdot \frac{d {ϕ}_{i}}{d {x}_{o}} {\vert}_{{x}_{o} = {x}_{{o}_{1 ∼ ∞}}} = 0 \\ tan {ϕ}_{o} \frac{d {ϕ}_{o}}{d λ} {\vert}_{λ = {λ}_{1} ∼ {λ}_{n}} = tan {ϕ}_{i} \cdot \frac{d {ϕ}_{i}}{d λ} {\vert}_{λ = {λ}_{1} ∼ {λ}_{n}} = 0\end{matrix}$$

φₒ is the object-space telecentricity. φᵢ is the image-space telecentricity. (xₒ, yₒ) are the coordinates of the object point. xₒ=xₒ_{_{1~∞}} is a central field position (namely, a central position of the slit, with coordinates (0, yₒ, 0)) to an edge field position (namely, an edge position of the slit, with coordinates (1, yₒ, 0)) of the slit of the spectrometer. (xᵢ, yᵢ) are the coordinates of the image point. λ is the wavelength. λ₁-λₙ is an operating wavelength range of the spectrometer. λ₁ is a start wavelength. λₙ is an end wavelength.

A curve function of the structure parameters of the meniscus lens and the primary reflector for object-space telecentricity is as follows:

$${ϕ}_{o} = {\sum }_{i = 1}^{3} {k}_{1 i} arcsin ( \frac{C 0}{{n}_{1 i} {R}_{i}} ) - {\sum }_{j = 1}^{2} {k}_{2 j} arcsin ( \frac{CO}{{n}_{2 j} {R}_{j}} )$$

k₁₃=2, and k₁ᵢ=1 for other values of i. n₁₂=n, and n₁ᵢ=1 for other values of i. k₂₂=2, and k₂ⱼ=1 for other values of j. n₂₁=n, and n₂ⱼ=1 for other values of j. CO is the distance from the object point of the spectrometer to the common center of curvature of all optical surfaces:

CO=\sqrt{xₒ²+yₒ²}

A curve function of the structure parameters of the meniscus lens and the secondary reflector for image-space telecentricity is as follows:

$${ϕ}_{i} = {\sum }_{i = 1}^{4} {k}_{1 i} arcsin ( \frac{CI}{{n}_{1 i} {R}_{i}} ) - {\sum }_{j = 1}^{2} {k}_{2 j} arcsin ( \frac{CI}{{n}_{2 j} {R}_{j}} )$$

k₁₄=2, k₁₃=0, and k₁ᵢ=1 for other values of i. n₁₂=n, and n₁ᵢ=1 for other values of i. k₂₂=2, and k₂ⱼ=1 for other values of j. n₂₁=n, and n₂ⱼ=1 for other values of j. CI is a distance from the image point of the spectrometer to the common center of curvature of all optical surfaces:

$$CI = \sqrt{{( {y}_{0} - {R}_{2} mg λ )}^{2} + {x}_{o}^{2}}$$

φₒ is the object-space telecentricity. φᵢ is the image-space telecentricity. (xₒ, yₒ) are the coordinates of the object point. n is a refractive index of the meniscus lens. m is the diffraction order. g is the groove density of the convex grating. λ is the wavelength. R₁ is a radius of curvature of a front surface of the meniscus lens. R₂ is the radius of curvature of the convex grating. R₃ is a radius of curvature of the primary reflector. R₄ is a radius of curvature of the secondary reflector. R₁ and R₃ are structure parameters determining the object-space telecentricity. R₁ and R₄ are structure parameters determining the image-space telecentricity. In the present disclosure, the first surface distribution may be obtained based on the structure parameter curve function corresponding φₒ, and the second surface distribution may be obtained based on the structure parameter curve function corresponding φᵢ.

The emergent azimuth angle αᵢ of the principal ray of the spectrometer is as follows:

$${α}_{i} = arctan ( \frac{{x}_{o}}{{y}_{o} - {R}_{2} m g λ} )$$

(xₒ, yₒ) are the coordinates of the object point. m is the diffraction order. g is the groove density of the convex grating. λ is the wavelength. R₂ is the radius of curvature of the convex grating.

In the present disclosure, the constraints on the telecentricity deviation and the telecentricity deviation change rate include: An allowable maximum telecentricity deviation is determined based on a high-quantitative spectral application requirement in engineering application, and both the telecentricity deviation and the telecentricity deviation change rate are constrained such that the telecentricity deviation of the system is less than a maximum telecentricity deviation corresponding to an engineering distortion requirement, the telecentricity deviation change rate is 0 when the telecentricity deviation is maximum, and the telecentricity deviation is 0 when the telecentricity deviation change rate is maximum. The engineering distortion requirement is used to expand a blur convergence interval and relax a distortion constraint, making blur quickly converge and ultimately achieving low distortion and a large image plane.

The maximum telecentricity deviation corresponding to the engineering distortion requirement is as follows:

$$\vert \frac{{y}_{o}}{2} ( {ϕ}_{o} {\vert}_{{( \frac{l}{2} , {y}_{o} , λ )}^{2}} - {ϕ}_{o} {\vert}_{{( o , {y}_{o} , λ )}^{2}} ) - \frac{1}{2} ( {y}_{o} - {R}_{2} * m g λ ) ( {ϕ}_{i} {\vert}_{{( \frac{l}{2} , {y}_{o} , λ )}^{2}} - {ϕ}_{i} {\vert}_{{( o , {y}_{o} , λ )}^{2}} ) \vert \leq 0.2 d \vert \frac{l}{4} ( {ϕ}_{i} {\vert}_{{( \frac{l}{2} , {y}_{o} , {λ}_{n} )}^{2}} - {ϕ}_{i} {\vert}_{{( \frac{l}{2} , {y}_{o} , {λ}_{1} )}^{2}} ) - {ϕ}_{o} {\vert}_{{( \frac{l}{2} , {y}_{o} , {λ}_{n} )}^{2}} - {ϕ}_{o} {\vert}_{{( \frac{l}{2} , {y}_{o} , {λ}_{1} )}^{2}} ) ] \vert \leq 0.2 d$$

φₒ is the object-space telecentricity. φᵢ is the image-space telecentricity. (xₒ, yₒ) are the coordinates of the object point. l is a length of any slit in the slits. (xᵢ, yᵢ) are the coordinates of the image point. R₂ is the radius of curvature of the convex grating. m is the diffraction order. g is the groove density of the convex grating. λ is the wavelength. λ₁-λₙ is an operating wavelength range of the spectrometer. λ₁ is the start wavelength. λₙ is the end wavelength. d is the pixel size of the spectral channel. The flatness threshold is 0.2d.

To extend a linear field of view of a conventional spectrometer to a large rectangular field of view, in an implementation process,

$$\frac{{l}^{2}}{{R}_{2}^{2}} + \frac{4}{F {\#}^{2}} = 1$$

may be used to implement a spectrometer with a long linear field of view, and

$$\frac{{l}^{2}}{{R}_{2}^{2}} + 4 {( \frac{1}{F \#} + \frac{h}{{R}_{2}} )}^{2} = 1$$

may be used to implement a spectrometer with the large rectangular field of view. l is the length of any slit in the slits. R₂ is the radius of curvature of the convex grating. F # is the F-number of the system. h is a width of the rectangular field of view.

In the present disclosure, a small-area array detector may be constructed into a large-area array detector for hyperspectral application, and the large rectangular field of view of the spectrometer may be set to two parallel slits. A horizontal direction of the two slits is set as follows: The two slits are discontinuously distributed, with discontinuities overlapping each other. An overlap length Lₒ depends on a drift angle θ_{Y} and satisfies Lₒ (min)>Lᵥ·tan(θ_{Y}(max)). A quantity of overlapping pixels is

$${N}_{o} = \frac{{L}_{o}}{d} .$$

A quantity of slit discontinuities in the horizontal direction is

$${N}_{h} = Int ( \frac{{N}_{s}}{{N}_{Dh} - {N}_{o}} ) .$$

A length of each slit discontinuity satisfies Lᵢ≤N_{Dh}·d. Lᵥ is the spacing between the two slits. d is the pixel size of the spectral channel. The drift angle θ_{Y} is an included angle between a satellite flight direction and the direction perpendicular to the slits. Lₒ(min) is a minimum value of Lₒ. θ_{Y}(max) is a maximum value of θ_{Y}. Nₛ is a total quantity of ground objects in spatial dimension. N_{Dh} is a quantity of pixels of the detector in spatial dimension.

A vertical direction of the two slits is set as follows: The spacing between the two slits satisfies Lᵥ=Lᵥ₁+Lᵥ₂+Lᵥ₃. Lᵥ₁=N_{λ}·d. N_{λ} is a quantity of spectral channels. Lᵥ₂=2 d₁+d₂. d₁ is a distance from an outermost effective pixel to an edge of the detector after packaging. d₂ is a minimum required spacing for a detector tiling process. Lᵥ₃=(N_{Dv}−N_{λ})·d. N_{Dv} is a quantity of pixels of the detector in spectral dimension. The small-area array detector is arranged in a staggered pattern. Different rows of the detector are sequentially aligned strictly with images of different wavelengths formed by the slits in image space of the spectrometer.

In the present disclosure, the large rectangular field of view of the spectrometer may be set to two parallel slits with a spacing of Lᵥ. The first slit (Slit1) uses a +2^{nd} or −2^{nd} order of the convex grating to perform spectral imaging on wavelengths λ₁ to λₙ. The second slit (Slit2) uses a +1^{st} or −1^{st} order of the convex grating to perform spectral imaging on wavelengths 2λ₁ to 2λₙ. A sum of a width Nd of an area array detector in spectral dimension and a mounting spacing ΔL between two detector chips is less than the spacing Lᵥ between the slits and greater than a spectral dispersion width h_{spec} of a single slit, to broaden a spectral range of the spectrometer from λ₁-λₙ to 2λ₁-2λₙ.

In the present disclosure, the large rectangular field of view of the spectrometer may be set to two parallel slits or a plurality of slits, with a same diffraction order for all slits of the spectrometer. A trajectory and a velocity of a moving target may be obtained through a position of the moving target in different slit fields of view and an elapsed time. If signals of a same target from N slits are superimposed, a signal-to-noise ratio of the target may be increased by a factor of \sqrt{N}. Target detection may be improved in a plurality of aspects through the plurality of slits.

The solution provided by the present disclosure is described below through two specific cases. A first case can implement a spectrometer with an ultra-long linear field of view and low distortion (the ultra-long linear field of view means that a slit length reaches 300 mm). A second case can implement a spectrometer with double slits, a large rectangular field of view, and low distortion (the large rectangular field of view is a field of view of 240 mm×32 mm). It should be noted that content in these cases is merely used to describe the solution of the present disclosure, and does not limit the protection scope of the present disclosure. Table 1 shows specifications and performance parameters of the spectrometer in the two cases.

TABLE 1
Example of the specifications and performance
parameters of the spectrometer

| | Case 1 (ultra- | Case 2 (large |
|---|---|---|
| | long linear | rectangular |
| | field of view) | field of view) |
| F-number | 3.6 | 3.6 |
| Slit length/mm | 300 | 240 |
| Spacing between two slits/mm | 0 | 32 |
| Spectral range/μm | 1.0-3.0 | 1.0-3.0 |
| Spectral resolution Δλ/nm | 10 | 10 |
| Pixel size/μm | 30 | 30 |
| Pixel size of a spectral | 60 | 60 |
| channel/μm | | |
| Diffraction order | −1 | −1 |
| Blur spot/μm | 10 | 10 |

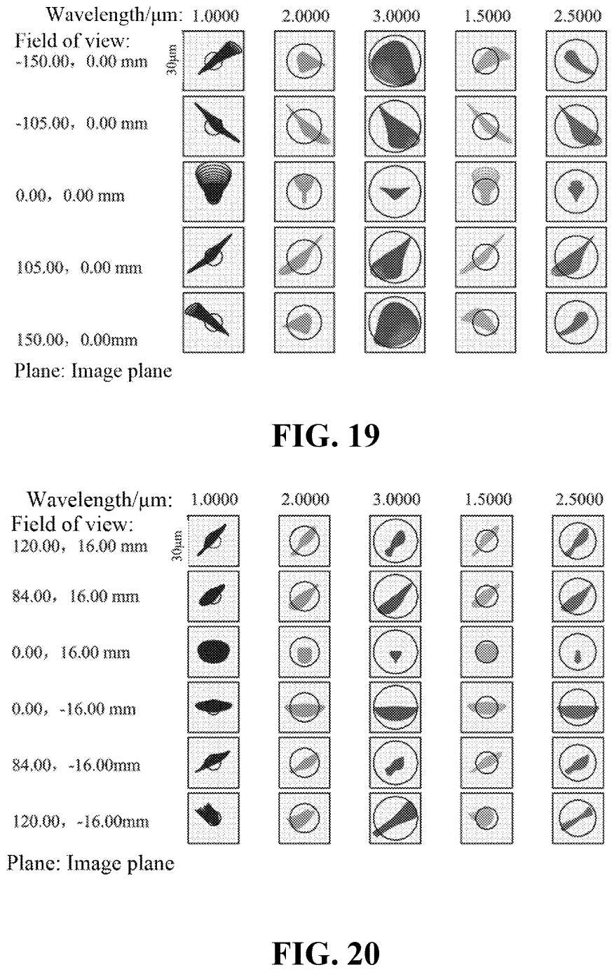

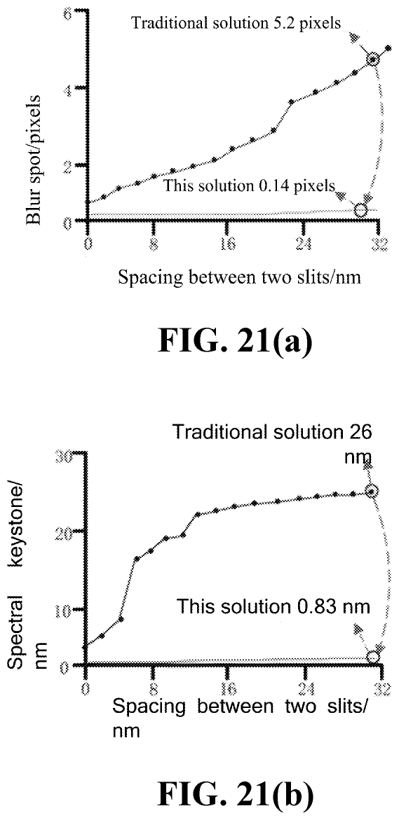

Table 2 shows simulation results of the two spectrometer cases. As shown in Table 2, the spectrometer provided in the present disclosure may have an ultra-long slit field of view of 300 mm and a large rectangular field of view of 240 mm×32 mm. Image quality is shown in Table 3 and Table 4. Spectral keystone is controlled within 0.2 pixels. A spectral lateral deviation is less than 0.1Δλ. Blur is close to a diffraction limit. Spot diagrams of the single-slit and double-slit spectrometers are respectively shown in FIG. 19 and FIG. 20. The blur is approximately ⅓ of a pixel. RMS (root mean square) represents a root mean square value of a distance between an actual imaging point of an optical system and an ideal image point. It is used to quantify blur of the optical system. A larger value indicates more significant aberration and lower image quality. MTF (modulation transfer function) is used to describe a contrast transfer capability of the optical system for different spatial frequencies. A higher curve indicates a stronger detail resolution capability and clearer imaging. Smile (spectral smile) is used to represent a deviation of a slit monochromatic image in a dispersion direction as a slit length increases. Keystone (spectral keystone) is used to represent a deviation of a spectral curve of a slit object in a spatial position direction due to dispersion at different wavelengths. As shown in FIG. 21(a) and FIG. 21(b), the present disclosure innovatively makes non-linearly surging blur and distortion become nearly constant. This major breakthrough overcomes a bottleneck that a field of view of a spectrometer cannot be lengthened or broadened.

It should be noted that the present disclosure is not limited to a single slit or double slits, but may also be applied to a rectangular field of view composed of a plurality of slits. The present disclosure is also not limited to short wave infrared of 1 μm to 3 μm, but may also be applied to other bands, including ultraviolet, visible, and very long wave.

TABLE 2
Structure parameters in telecentricity calculation for the spectrometer and optimized
structure parameters

| | 300 mm single slit | | 240 mm × 32 mm double slits | |
|---|---|---|---|---|
| | Normalized | | Normalized | |
| | initial | Optimized | initial | Optimized |
| | parameter/R₂ | parameter/mm | parameter/R₂ | parameter/mm |
| Front surface of a | 0.819 | −350.33 | 0.822 | −379.270 |
| meniscus lens R₁ | | | | |
| Rear surface of the | 1 | −398.659 | 1 | −425.626 |
| meniscus lens R₁′ | | | | |
| Radius of curvature of a | 1 | −365.379 | 1 | −364.498 |
| convex grating R₂ | | | | |
| Radius of curvature of a | 2.14 | −729.404 | 2.13 | −739.954 |
| primary reflector R₃ | | | | |
| Radius of curvature of a | 2.14 | −732.438 | 2.13 | −743.435 |
| secondary reflector R₄ | | | | |

In the single-slit case, R₂ = 365.85, and normalized initial structure parameters are converted to non-normalized initial structure parameters.
In the double-slit case, R₂ = 363.64, and normalized initial structure parameters are converted to non-normalized initial structure parameters.

TABLE 3
Image quality of the spectrometer in Case 1

| | Ultra-long linear field of view of 300 mm | | | | |
|---|---|---|---|---|---|
| Spectrometer case 1 | 1.0 μm | 1.5 μm | 2.0 μm | 2.5 μm | 3.0 μm |
| Diffraction limit/μm | 4.328 | 6.493 | 8.657 | 10.82 | 12.99 |
| RMS/μm | 6.524 | 6.031 | 6.107 | 6.260 | 8.037 |
| MTF | ≥0.81 | ≥0.81 | ≥0.78 | ≥0.75 | ≥0.68 |

| | |
|---|---|
| Smile/μm | ≤3.619 |
| Keystone/μm | ≤5.125 |
| Spectral lateral deviation/nm | ≤0.3 |

TABLE 4
Image quality of the spectrometer in Case 2

| Spectrometer | Large rectangular field of view of 240 mm × 32 mm | | | | |
|---|---|---|---|---|---|
| case 2 | 1.0 μm | 1.5 μm | 2.0 μm | 2.5 μm | 3.0 μm |
| Diffraction | 4.327 | 6.491 | 8.657 | 10.82 | 12.98 |
| limit/μm | | | | | |
| RMS/μm | 5.994 | 5.763 | 6.149 | 6.665 | 9.054 |
| MTF | ≥0.82 | ≥0.78 | ≥0.76 | ≥0.69 | ≥0.59 |
| Smile/μm | ≤5.430 | | | | |
| Keystone/μm | ≤3.079 | | | | |
| Spectral lateral | ≤0.5 | | | | |
| deviation/nm | | | | | |

In the present disclosure, the computer device may be a desktop computer, a notebook computer, a palmtop computer, a cloud server, or the like. The processor may be a central processing unit (CPU), or may be another general-purpose processor, a digital signal processor (DSP), an application-specific integrated circuit (ASIC), a field-programmable gate array (FPGA) or another programmable logic device, a discrete gate, a transistor logic device, a discrete hardware component, or the like. The general-purpose processor may be a microprocessor, or the processor may be any conventional processor or the like.

The present disclosure further includes a memory. The memory may be configured to store data, a computer program and/or modules, and the like. The processor implements design of the hyperspectral imaging spectrometer with low distortion, a large image plane, and object- and image-space telecentricity by running or executing the computer program and/or modules stored in the memory and invoking the data stored in the memory. The memory may include a high-speed random access memory, and may further include a non-volatile memory, such as a hard disk, an internal storage, a removable hard disk, a smart media card (SMC), a secure digital (SD) card, a flash card, at least one magnetic disk storage device, a flash memory device, or another volatile solid-state storage device.

In summary, the present disclosure proposes a telecentricity implementation model of the spectrometer, and systematically analyzes and optimizes key parameters in complex spectrometer design through the theoretical model for the first time. Under guidance of the theoretical model, the initial structure parameters of the spectrometer are further determined, and an innovative spectrometer featuring a large field of view, high image quality, and extremely low spectral keystone and lateral deviation is successfully designed. With its superior performance, the spectrometer breaks through a technical bottleneck that a conventional spectrometer is difficult to balance between a large field of view and high accuracy, and creates a new path for high-performance spectrometer design.

In addition, the present disclosure adopts a spectrometer design method with object- and image-space telecentricity as a core for the first time, and converts a traditional complex aberration optimization problem into a simple parameter solving problem by reconstructing a quantitative relationship between telecentricity design and optical structure parameters. The initial structure obtained through this method features extremely low spectral keystone and lateral deviation, requiring only simple subsequent optimization to meet high-accuracy engineering design requirements. More importantly, this method innovatively resolves a problem that blur and distortion of the spectrometer non-linearly surge as a field of view increases, achieving nearly constant spectral keystone and lateral deviation in a large field of view. This breakthrough innovation overcomes traditional technical limitations on a length and width of the field of view of the spectrometer, provides theoretical support for engineering application of a wide-spectrum and wide-swath spaceborne hyperspectral imager, and lays a foundation for development of spaceborne wide-spectrum and wide-swath hyperspectral imaging.

In addition, the solution provided by the present disclosure can resolve a technical problem of designing a spectrometer with a rectangular field of view under conditions of a small F-number, low distortion, and high image quality. A spectrometer with a large rectangular field of view provides a feasible scheme for application of a small-area array detector with tiling in a staggered pattern in a spaceborne wide-swath hyperspectral payload. This technical breakthrough not only significantly improves engineering efficiency of a spaceborne hyperspectral spectrometer, but also successfully shortens a research and development period of a spaceborne wide-spectrum wide-swath hyperspectral payload by 5 to 10 years. It accelerates implementation of an ultra-wide-swath, high-quantitative, and high-accuracy spaceborne hyperspectral remote sensing technology, and provides important technical guarantee for future in-orbit remote sensing detection and resource monitoring. Further, the large rectangular field of view of the spectrometer is set to two parallel slits or a plurality of slits such that a spectral range can be broadened several times under different grating diffraction orders, a trajectory and a velocity of a moving target can be obtained under a same grating diffraction order, or a signal-to-noise ratio of a static target can be improved several times. The solution provided by the present disclosure enables a leap forward in spectrometer design, from theoretical innovation to engineering application. Its achievements hold significant scientific value and engineering significance, supporting in-orbit application of spaceborne wide-spectrum wide-swath hyperspectral cameras and significantly advancing technological progress in fields such as remote sensing, environmental monitoring, and resource detection.

The foregoing content is merely intended to exemplarily explain the principles and effects of the present disclosure, rather than limit the present disclosure. Any person skilled in the art can make modifications or changes to the foregoing content without departing from the spirit and scope of the present disclosure. Hence, all equivalent modifications or changes made by those of ordinary skill in the art without departing from the spirit and technical teachings disclosed in the present disclosure should fall within the scope defined by appended claims to the present disclosure.

1. An implementation method of a hyperspectral imaging spectrometer with low distortion, a large image plane, and object- and image-space telecentricity, executed by a computer device or a processor and comprising: establishing a theoretical model for object- and image-space telecentricity of the spectrometer, designing initial structure parameters of the spectrometer based on the theoretical model, and determining a relationship between telecentricity and parameters of a field stop with slits, a meniscus lens, a primary reflector, a secondary reflector, and a convex grating that are comprised in the spectrometer; wherein
a design method for the initial structure parameters of the spectrometer comprises: determining initial structure parameters R₁, R₂, R₃, and R₄ of the spectrometer and off-axis distances yₒ₁ and yₒ₂ of the slits, wherein R₁ is a radius of curvature of a front surface of the meniscus lens, R₂ is a radius of curvature of the convex grating, R₃ is a radius of curvature of the primary reflector, and R₄ is a radius of curvature of the secondary reflector;
a process of determining an initial structure of the spectrometer comprises:
S51: obtaining a first input parameter and a second input parameter;
S52: obtaining an intermediate parameter based on the first input parameter and the second input parameter;
S53: solving an object-space telecentricity model and an image-space telecentricity model;
S54: obtaining the initial structure parameters;
S55: determining whether an initial structure corresponding to the initial structure parameters blocks light;
S56: determining whether the initial structure meets a spectral detection requirement for engineering application; and
S57: if determining in S55 that light is not blocked and in S56 that the spectral detection requirement for engineering application is met, outputting the initial structure parameters and establishing the initial structure of the spectrometer;
the theoretical model comprises a “spectral smile-telecentricity” model, a “spectral keystone-telecentricity” model, and an “astigmatism-telecentricity” model;
a method for solving the object-space telecentricity model and the image-space telecentricity model in the design method is as follows: obtaining a first surface distribution and a second surface distribution based on the theoretical model, wherein the first surface distribution is a surface distribution of structure parameters of the meniscus lens and the primary reflector with respect to a two-dimensional rectangular field of view when object-space telecentricity is achieved, and a curve function of the structure parameters is as follows:
$${ϕ}_{o} = {\sum }_{i = 1}^{3} {k}_{1 i} arcsin ( \frac{C 0}{{n}_{1 i} {R}_{i}} ) - {\sum }_{j = 1}^{2} {k}_{2 j} arcsin ( \frac{CO}{{n}_{2 j} {R}_{j}} )$$
wherein k₁₃=2, and k₁ᵢ=1 for other values of i; n₁₂=n, and n₁ᵢ=1 for other values of i; k₂₂=2, and k₂ⱼ, =1 for other values of j; n₂₁=n, and n₂ⱼ=1 for other values of j; and CO is a distance from an object point of the spectrometer to a common center of curvature C of all optical surfaces:
CO=\sqrt{xₒ²+yₒ²}
the second surface distribution is a surface distribution of structure parameters of the meniscus lens and the secondary reflector with respect to the two-dimensional rectangular field of view when image-space telecentricity is achieved, and a curve function of the structure parameters is as follows:
$${ϕ}_{i} = {\sum }_{i = 1}^{4} {k}_{1 i} arcsin ( \frac{CI}{{n}_{1 i} {R}_{i}} ) - {\sum }_{j = 1}^{2} {k}_{2 j} arcsin ( \frac{CI}{{n}_{2 j} {R}_{j}} )$$
wherein k₁₄=2, k₁₃=0, and k₁ᵢ=1 for other values of i; n₁₂=n, and n₁ᵢ=1 for other values of i; k₂₂=2, and k₂ⱼ=1 for other values of j; n₂₁=n, and n₂ⱼ=1 for other values of j; and CI is a distance from an image point of the spectrometer to the common center of curvature C of all optical surfaces:
$$CI = \sqrt{{( {y}_{0} - {R}_{2} mg λ )}^{2} + {x}_{o}^{2}}$$
wherein φₒ is the object-space telecentricity, with clockwise as a positive direction; φᵢ is the image-space telecentricity, with counterclockwise as a positive direction; (xₒ, yₒ) are coordinates of the object point; n is a refractive index of the meniscus lens; m is a diffraction order; g is a groove density of the convex grating; λ is a wavelength; R₁ and R₃ are structure parameters determining the object-space telecentricity; and R₁ and R₄ are structure parameters determining the image-space telecentricity.

2. The implementation method according to claim 1, wherein
the “spectral smile-telecentricity” model is as follows:
$${ε}_{s} = \frac{d {y}_{i}}{d {x}_{o}} = [ {y}_{0} tan {ϕ}_{o} \cdot \frac{d {ϕ}_{o}}{d {x}_{o}} + ( \frac{{R}_{g} \cdot mg λ}{cos {ϕ}_{o}} - {y}_{o} ) \cdot tan {ϕ}_{i} \cdot \frac{d {ϕ}_{i}}{d {x}_{o}} ] \cdot \frac{cos {ϕ}_{o}}{cos {ϕ}_{i}}$$
the “spectral keystone-telecentricity” model is as follows:
$${ε}_{k} = \frac{d {x}_{i}}{d λ} = [ tan {ϕ}_{o} \frac{d {ϕ}_{o}}{d λ} - tan {ϕ}_{i} \cdot \frac{d {ϕ}_{i}}{d λ} ] \cdot {x}_{o} \cdot \frac{cos {ϕ}_{o}}{cos {ϕ}_{i}}$$
the “astigmatism-telecentricity” model is as follows:
$${ε}_{a} = \frac{sin {α}_{o}}{sin {α}_{i}} \cdot CO \cdot tan [ {ϕ}_{i} + arctan ( \frac{sin {α}_{i}}{sin {α}_{o}} \cdot tan {ϕ}_{o} ) ]$$
wherein εₛ is a value of spectral smile; εₖ is a value of spectral keystone; εₐ is a value of astigmatism; (xᵢ, yᵢ) are coordinates of the image point; and αₒ is an incident azimuth angle of a principal ray of the spectrometer, and αᵢ is an emergent azimuth angle of the principal ray of the spectrometer, with clockwise as a positive direction.

3. The implementation method according to claim 1, wherein parameters of the spectrometer satisfy following formula:
$$\{ \begin{matrix}tan {ϕ}_{o} \cdot \frac{d {ϕ}_{o}}{d {x}_{o}} {\vert}_{{x}_{o} = {x}_{{o}_{1 ∼ ∞}}} = tan {ϕ}_{i} \cdot \frac{d {ϕ}_{i}}{d {x}_{o}} {\vert}_{{x}_{o} = {x}_{{o}_{1 ∼ ∞}}} = 0 \\ tan {ϕ}_{o} \frac{d {ϕ}_{o}}{d λ} {\vert}_{λ = {λ}_{1} ∼ {λ}_{n}} = tan {ϕ}_{i} \cdot \frac{d {ϕ}_{i}}{d λ} {\vert}_{λ = {λ}_{1} ∼ {λ}_{n}} = 0\end{matrix}$$
wherein xₒ=xₒ_{_{1~∞}} is a central field position to an edge field position of any slit in the slits of the spectrometer, λ₁-λₙ is an operating wavelength range of the spectrometer, λ₁ is a start wavelength, and λₙ is an end wavelength.

4. The implementation method according to claim 1, wherein each of the slits is located on a plane perpendicular to an optical axis and passing through the common center of curvature C of all optical surfaces, a zₒ coordinate of any point on the slit is zero, and the slit is parallel to an x-axis and at a distance of yₒ₁ or yₒ₂ from the common center of curvature C.

5. The implementation method according to claim 1, wherein
a functional relationship between the object-space telecentricity and the structure parameters of the meniscus lens and the primary reflector is as follows:
φₒ=2θ₃ₒ−θ₄ₒ+Δφₒ
wherein Δφₒ is an object-space telecentricity adjustment factor introduced by the meniscus lens:
$$Δ {ϕ}_{o} = {θ}_{1 o} + {θ}_{2 o} - {θ}_{1 o}^{′} - {θ}_{2 o}^{′}$$
θ₁ₒ is an incident angle of an object-space principal ray on the front surface of the meniscus lens:
$${θ}_{1 o} = arcsin ( \frac{CO}{{R}_{1}} )$$
$${θ}_{1 o}^{′}$$
is an emergent angle of the object-space principal ray on the front surface of the meniscus lens:
$${θ}_{1 o}^{′} = arcsin ( \frac{CO}{{nR}_{1}} )$$
θ₂ₒ is an incident angle of the object-space principal ray on a rear surface of the meniscus lens:
$${θ}_{2 o} = arcsin ( \frac{CO}{n {R}_{2}} )$$
$${θ}_{2 o}^{′}$$
is an emergent angle of the object-space principal ray on the rear surface of the meniscus lens:
$${θ}_{2 o}^{′} = arcsin ( \frac{CO}{{R}_{2}} )$$
θ₃ₒ is an incident angle of the object-space principal ray on the primary reflector:
$${θ}_{3 o} = arcsin ( \frac{CO}{{R}_{3}} )$$
θ₄ₒ is an incident angle of the object-space principal ray on the convex grating:
$${θ}_{4 o} = arcsin ( \frac{CO}{{R}_{2}} )$$
a functional relationship between the image-space telecentricity and the structure parameters of the meniscus lens and the secondary reflector is as follows:
φᵢ=2θ₃ᵢ−θ₄ᵢ+Δφᵢ
wherein Δφᵢ is an image-space telecentricity adjustment factor introduced by the meniscus lens:
$$Δ {ϕ}_{i} = {θ}_{1 i} + {θ}_{2 i} - {θ}_{1 i}^{′} - {θ}_{2 i}^{′}$$
θ₁ᵢ is an emergent angle of an image-space principal ray on the front surface of the meniscus lens:
$${θ}_{1 i} = arcsin ( \frac{CI}{{R}_{1}} )$$
$${θ}_{1 i}^{′}$$
is an incident angle of the image-space principal ray on the front surface of the meniscus lens:
$${θ}_{1 i}^{′} = arcsin ( \frac{CI}{{nR}_{1}} )$$
θ₂ᵢ is an emergent angle of the image-space principal ray on the rear surface of the meniscus lens:
$${θ}_{2 i} = arcsin ( \frac{CI}{{nR}_{2}} )$$
$${θ}_{2 i}^{′}$$
is an incident angle of the image-space principal ray on the rear surface of the meniscus lens:
$${θ}_{2 i}^{′} = arcsin ( \frac{CI}{{R}_{2}} )$$
θ₃ᵢ is an emergent angle of the image-space principal ray on the secondary reflector:
$${θ}_{3 i} = arc sin ( \frac{CI}{{R}_{4}} )$$
θ₄ᵢ is an emergent angle of the image-space principal ray on the convex grating:
$${θ}_{4 i} = arc sin ( \frac{CI}{{R}_{2}} ) .$$

6. The implementation method according to claim 1, further comprising: under constraints on a telecentricity deviation and a telecentricity deviation change rate, respectively profiling the first surface distribution and the second surface distribution along a direction of the slits and a direction perpendicular to the slits to obtain profile curves; and selecting parameters corresponding to curves with flatness less than a flatness threshold from the profile curves as the initial structure parameters of the spectrometer; wherein
the constraints on the telecentricity deviation and the telecentricity deviation change rate comprise: the telecentricity deviation of the spectrometer is less than a maximum telecentricity deviation corresponding to an engineering distortion requirement, the telecentricity deviation change rate is 0 when the telecentricity deviation is maximum, and the telecentricity deviation is 0 when the telecentricity deviation change rate is maximum.

7. The implementation method according to claim 6, wherein the maximum telecentricity deviation corresponding to the engineering distortion requirement is as follows:
$$\vert \frac{{y}_{o}}{2} ( {ϕ}_{o} {\vert}_{( \frac{l}{2} {y}_{o} , λ )}^{2} - {ϕ}_{o} {\vert}_{( 0 , {y}_{o} , λ )}^{2} ) - \frac{1}{2} ( {y}_{o} - {R}_{2} * mg λ ) ( {ϕ}_{i} {\vert}_{( \frac{l}{2} , {y}_{o} , λ )}^{2} - {ϕ}_{i} {\vert}_{( 0 , {y}_{o} , λ )}^{2} ) \vert \leq 0.2 d$$
$$\vert \frac{l}{4} [ ( {ϕ}_{i} {\vert}_{( \frac{l}{2} {y}_{o} , {λ}_{n} )}^{2} - {ϕ}_{i} {\vert}_{( \frac{l}{2} {y}_{o} , {λ}_{1} )}^{2} ) - ( {ϕ}_{o} {\vert}_{( \frac{l}{2} {y}_{o} , {λ}_{n} )}^{2} - {ϕ}_{o} {\vert}_{( \frac{l}{2} {y}_{o} , {λ}_{1} )}^{2} ) ] \vert \leq 0.2 d$$
wherein l is a length of any slit in the slits, λ₁-λₙ is an operating wavelength range of the spectrometer, λ₁ is a start wavelength, λₙ is an end wavelength, and d is a pixel size of a spectral channel.

8. The implementation method according to claim 7, wherein the engineering distortion requirement is used to expand a blur convergence interval and relax a distortion constraint, making blur converge and ultimately achieving low distortion and a large image plane.

9. The implementation method according to claim 1, wherein the implementation method extends a linear field of view of a conventional spectrometer to a large rectangular field of view, and in the implementation method:
$$\frac{{l}^{2}}{{R}_{2}^{2}} + \frac{4}{F {\#}^{2}} = 1$$
the foregoing formula is used to implement a spectrometer with a long linear field of view;
$$\frac{{l}^{2}}{{R}_{2}^{2}} + 4 {( \frac{1}{F \#} + \frac{h}{{R}_{2}} )}^{2} = 1$$
the foregoing formula is used to implement a spectrometer with the large rectangular field of view, wherein l is a length of any slit in the slits, F # is an F-number of a system, and h is a width of the rectangular field of view.

10. The implementation method according to claim 2, wherein the implementation method extends a linear field of view of a conventional spectrometer to a large rectangular field of view, and in the implementation method:
$$\frac{{l}^{2}}{{R}_{2}^{2}} + \frac{4}{F {\#}^{2}} = 1$$
the foregoing formula is used to implement a spectrometer with a long linear field of view;
$$\frac{{l}^{2}}{{R}_{2}^{2}} + 4 {( \frac{1}{F \#} + \frac{h}{{R}_{2}} )}^{2} = 1$$
the foregoing formula is used to implement a spectrometer with the large rectangular field of view, wherein l is a length of any slit in the slits, F # is an F-number of a system, and h is a width of the rectangular field of view.

11. The implementation method according to claim 7, wherein the implementation method extends a linear field of view of a conventional spectrometer to a large rectangular field of view, and in the implementation method:
$$\frac{{l}^{2}}{{R}_{2}^{2}} + \frac{4}{F {\#}^{2}} = 1$$
the foregoing formula is used to implement a spectrometer with a long linear field of view;
$$\frac{{l}^{2}}{{R}_{2}^{2}} + 4 {( \frac{1}{F \#} + \frac{h}{{R}_{2}} )}^{2} = 1$$
the foregoing formula is used to implement a spectrometer with the large rectangular field of view, wherein l is the length of any slit in the slits, F # is an F-number of a system, and h is a width of the rectangular field of view.

12. The implementation method according to claim 1, wherein the implementation method constructs a small-area array detector into a large-area array detector for hyperspectral application, and sets a large rectangular field of view of the spectrometer to two parallel slits;
a horizontal direction of the two slits is set as follows: the two slits are discontinuously distributed, with discontinuities overlapping each other, an overlap length Lₒ depends on a drift angle θ_{Y} and satisfies Lₒ(min)>Lᵥ·tan(θ_{y}(max)), a quantity of overlapping pixels is
$${N}_{o} = \frac{{L}_{o}}{d} ,$$
a quantity of slit discontinuities in the horizontal direction is
$${N}_{h} = Int ( \frac{{N}_{s}}{{N}_{D h} - {N}_{o}} ) ,$$
a length of each slit discontinuity satisfies Lᵢ≤N_{Dh}·d, Lᵥ is a spacing between the two slits, d is a pixel size of the spectral channel, the drift angle θ_{Y} is an included angle between a satellite flight direction and the direction perpendicular to the slits, Lₒ(min) is a minimum value of Lₒ, θ_{Y}(max) is a maximum value of θ_{Y}, Nₛ is a total quantity of ground objects in spatial dimension, and N_{Dh} is a quantity of pixels of the detector in spatial dimension;
a vertical direction of the two slits is set as follows: the spacing between the two slits satisfies Lᵥ=Lᵥ₁+Lᵥ₂+Lᵥ₃, Lᵥ₁=N_{λ}·d, N_{λ} is a quantity of spectral channels, Lᵥ₂=2·d₁+d₂, d₁ is a distance from an outermost effective pixel to an edge of the detector after packaging, d₂ is a minimum required spacing for a detector tiling process, Lᵥ₃=(N_{Dv}−N_{λ})·d, and N_{Dv} is a quantity of pixels of the detector in spectral dimension; and
the small-area array detector is arranged in a staggered pattern, and different rows of the detector are sequentially aligned strictly with images of different wavelengths formed by the slits in image space of the spectrometer.

13. The implementation method according to claim 2, wherein the implementation method constructs a small-area array detector into a large-area array detector for hyperspectral application, and sets a large rectangular field of view of the spectrometer to two parallel slits;
a horizontal direction of the two slits is set as follows: the two slits are discontinuously distributed, with discontinuities overlapping each other, an overlap length Lₒ depends on a drift angle θ_{Y} and satisfies Lₒ(min)>Lᵥ·tan(θ_{Y}(max)), a quantity of overlapping pixels is
$${N}_{o} = \frac{{L}_{o}}{d} ,$$
a quantity of slit discontinuities in the horizontal direction is
$${N}_{h} = Int ( \frac{{N}_{s}}{{N}_{D h} - {N}_{o}} ) ,$$
a length of each slit discontinuity satisfies Lᵢ≤N_{Dh}·d, Lᵥ is a spacing between the two slits, d is a pixel size of the spectral channel, the drift angle θ_{Y} is an included angle between a satellite flight direction and the direction perpendicular to the slits, Lₒ(min) is a minimum value of Lₒ, θ_{Y}(max) is a maximum value of θ_{Y}, Nₛ is a total quantity of ground objects in spatial dimension, and N_{Dh} is a quantity of pixels of the detector in spatial dimension;
a vertical direction of the two slits is set as follows: the spacing between the two slits satisfies Lᵥ=Lᵥ₁+Lᵥ₂+Lᵥ₃, Lᵥ₁=N_{λ}·d, N_{λ} is a quantity of spectral channels, Lᵥ₂=2·d₁+d₂, d₁ is a distance from an outermost effective pixel to an edge of the detector after packaging, d₂ is a minimum required spacing for a detector tiling process, Lᵥ₃=(N_{Dv}−N_{λ})·d, and N_{Dv} is a quantity of pixels of the detector in spectral dimension; and
the small-area array detector is arranged in a staggered pattern, and different rows of the detector are sequentially aligned strictly with images of different wavelengths formed by the slits in image space of the spectrometer.

14. The implementation method according to claim 7, wherein the implementation method constructs a small-area array detector into a large-area array detector for hyperspectral application, and sets a large rectangular field of view of the spectrometer to two parallel slits;
a horizontal direction of the two slits is set as follows: the two slits are discontinuously distributed, with discontinuities overlapping each other, an overlap length Lₒ depends on a drift angle θ_{Y} and satisfies Lₒ(min)>Lᵥ·tan(θ_{y}(max)), a quantity of overlapping pixels is
$${N}_{o} = \frac{{L}_{o}}{d} ,$$
a quantity of slit discontinuities in the horizontal direction is
$${N}_{h} = Int ( \frac{{N}_{s}}{{N}_{D h} - {N}_{o}} ) ,$$
a length of each slit discontinuity satisfies Lᵢ≤N_{Dh}·d, Lᵥ is a spacing between the two slits, dis the pixel size of the spectral channel, the drift angle θ_{Y} is an included angle between a satellite flight direction and the direction perpendicular to the slits, Lₒ(min) is a minimum value of Lₒ, θ_{Y}(max) is a maximum value of θ_{Y}, Nₛ is a total quantity of ground objects in spatial dimension, and N_{Dh} is a quantity of pixels of the detector in spatial dimension;
a vertical direction of the two slits is set as follows: the spacing between the two slits satisfies Lᵥ=Lᵥ₁+Lᵥ₂+Lᵥ₃, Lᵥ₁=N_{λ}·d, N_{λ} is a quantity of spectral channels, Lᵥ₂=2·d₁+d₂, d₁ is a distance from an outermost effective pixel to an edge of the detector after packaging, d₂ is a minimum required spacing for a detector tiling process, Lᵥ₃=(N_{Dv}−N_{λ})·d, and N_{Dv} is a quantity of pixels of the detector in spectral dimension; and
the small-area array detector is arranged in a staggered pattern, and different rows of the detector are sequentially aligned strictly with images of different wavelengths formed by the slits in image space of the spectrometer.

15. The implementation method according to claim 1, wherein a large rectangular field of view of the spectrometer is set to two parallel slits with a spacing of Lᵥ, a first slit of the two parallel slits uses a +2^{nd} or −2^{nd} order of the convex grating to perform spectral imaging on wavelengths λ₁ to λₙ, a second slit of the two parallel slits uses a +1^{st} or −1^{st} order of the convex grating to perform spectral imaging on wavelengths λ2₁ to 2λₙ, and a sum of a width Nd of an area array detector in spectral dimension and a mounting spacing ΔL between two detector chips is less than the spacing L, between the slits and greater than a spectral dispersion width h_{spec} of a single slit, to broaden a spectral range of the spectrometer from λ₁-λₙ to 2λ₁-2λₙ.

16. The implementation method according to claim 3, wherein a large rectangular field of view of the spectrometer is set to two parallel slits with a spacing of Lᵥ, a first slit of the two parallel slits uses a +2^{nd} or −2^{nd} order of the convex grating to perform spectral imaging on wavelengths λ₁ to λₙ, a second slit of the two parallel slits uses a +1^{st} or −1^{st} order of the convex grating to perform spectral imaging on wavelengths 2λ₁ to 2λₙ, and a sum of a width Nd of an area array detector in spectral dimension and a mounting spacing ΔL between two detector chips is less than the spacing Lᵥ between the slits and greater than a spectral dispersion width h_{spec} of a single slit, to broaden a spectral range of the spectrometer from λ₁-λₙ to 2λ₁-2λₙ.

17. The implementation method according to claim 7, wherein a large rectangular field of view of the spectrometer is set to two parallel slits with a spacing of Lᵥ, a first slit of the two parallel slits uses a +2^{nd} or −2^{nd} order of the convex grating to perform spectral imaging on wavelengths λ₁ to λₙ, a second slit of the two parallel slits uses a +1^{st} or −1^{st} order of the convex grating to perform spectral imaging on wavelengths 2λ₁ to 2λₙ, and a sum of a width Nd of an area array detector in spectral dimension and a mounting spacing ΔL between two detector chips is less than the spacing Lᵥ between the slits and greater than a spectral dispersion width h_{spec} of a single slit, to broaden a spectral range of the spectrometer from λ₁-λₙ to 2λ₁-2λₙ.

18. The implementation method according to claim 1, wherein a large rectangular field of view of the spectrometer is set to two parallel slits or a plurality of slits, with a same diffraction order for all slits of the spectrometer;
a trajectory and a velocity of a moving target are obtained through a position of the moving target in different slit fields of view and an elapsed time;
if signals of a same target from N slits are superimposed, a signal-to-noise ratio of the target is increased by a factor of \sqrt{N}; and
target detection is improved in a plurality of aspects through the plurality of slits.

19. The implementation method according to claim 2, wherein a large rectangular field of view of the spectrometer is set to two parallel slits or a plurality of slits, with a same diffraction order for all slits of the spectrometer;
a trajectory and a velocity of a moving target are obtained through a position of the moving target in different slit fields of view and an elapsed time;
if signals of a same target from N slits are superimposed, a signal-to-noise ratio of the target is increased by a factor of \sqrt{N}; and
target detection is improved in a plurality of aspects through the plurality of slits.

20. A spectrometer, wherein the spectrometer is implemented through the implementation method according to claim 1.
